(19) United States
(12) Patent Application Publication
(10) Pub. No.: US 2025/0203936 A1
(43) Pub. Date: Jun. 19, 2025

(54) FORKSHEET DEVICE WITH WRAPPED CONTACT

(71) Applicant: INTERNATIONAL BUSINESS MACHINES CORPORATION, ARMONK, NY (US)

(72) Inventors: Ruilong Xie, Niskayuna, NY (US); Ashim Dutta, Clifton Park, NY (US); Shravana Kumar Katakam, Lehi, UT (US); Nicholas Alexander Polomoff, Hopewell Junction, NY (US); Kisik Choi, Watervliet, NY (US)

(21) Appl. No.: 18/543,663

(22) Filed: Dec. 18, 2023

(51) Int. Cl. H01L 29/423; H01L 21/8238; H01L 27/092; H01L 29/06; H01L 29/08; H01L 29/66; H01L 29/775; H01L 29/786

(52) U.S. Cl. CPC H10D 30/6735; H10D 30/014; H10D 30/43; H10D 30/6757; H10D 62/121; H10D 62/151; H10D 64/017; H10D 84/0167; H10D 84/0186; H10D 84/038; H10D 84/85

(57) ABSTRACT

A semiconductor structure, a system, and a method of forming a transistor with a dielectric bar and a wrapped contact. The semiconductor structure may include a first transistor. The first transistor may include an epi. The first transistor may also include a dielectric bar. The first transistor may also include a wrapped contact, where the wrapped contact has direct contact with three or more sides of the epi. The system may include a semiconductor structure. The method may include forming a set of stacked nanosheets. The method may also include forming a dielectric bar. The method may also include growing an epi. The method may also include performing an epi cut to remove portions of the epi. The method may also include depositing metal contact around the two or more sides of the epi. The method may also include depositing dielectric to separate portions of the metal contact.

### BACKGROUND

The present disclosure relates to semiconductors and transistors and, more specifically, to field-effect transistors (FETs) and forksheets/dielectric bars. Semiconductors, such as complementary metal-oxide-semiconductors (CMOS), are commonly used in computer chips and computer technology. These semiconductor chips/devices typically include transistor(s). Transistors are devices which may be used to switch or amplify electric current or voltage.

FETs use an electric field effect to control current flow within a semiconductor. FETs have three terminals—a source, a drain, and a gate. The source introduces/provides current to the transistor, the drain is the terminal that provides the output current, and the gate is used to control the current flow from the source to the drain. Specifically, FETs use the electric charge of their gates to affect and control the current flow through the channel.

Current flows using charge carriers that are either electrons or holes. Electron charge carriers are negatively charged particles (i.e., electrons) that carry charge and create an electric current. Hole charge carriers (referred to herein as holes) are positions on the FET channel that lack an electron (for instance, at positions of positive charge that is equal in magnitude to the negative charge of an electron and/or positions where an electron could or should be). These holes are positive charges, and they move in an opposite direction of electrons, in some instances. The electric charge and/or voltage of the FET gates is used to control the movements of the electrons and/or holes, which can then affect the current and charge being transmitted through the channel from the source to the drain.

One common type of FET is a finFET. FinFETs, as referred to herein, may be FETs in a vertical fin shape. FinFETs may have vertically stacked channels, and vertically stacked components in general, in order to form the tall, narrow fin shape of a finFET. Another common type of FET is a nanosheet FET. Nanosheet FETs may have multiple nanosheets stacked (for example, vertically and/or horizontally) above/below each other.

### SUMMARY

The present disclosure provides a semiconductor structure, a system, and a method of forming a transistor with a forksheet/dielectric bar and a wrapped contact. The semiconductor structure may include a first transistor. The first transistor may include an epi. The first transistor may also include a dielectric bar. The first transistor may also include a wrapped contact, where the wrapped contact has direct contact with three or more sides of the epi.

The system may include a semiconductor structure. The semiconductor structure may include a first transistor. The first transistor may include an epi. The first transistor may also include stacked nanosheets. The first transistor may also include a dielectric bar, where the dielectric bar is directly connected to the stacked nanosheets. The first transistor may also include a wrapped contact, where the wrapped contact has direct contact with three or more sides of the epi.

The method may include forming a set of stacked nanosheets. The method may also include forming a dielectric bar, where the dielectric bar is directly connected to the set of stacked nanosheets. The method may also include growing an epi. The method may also include performing an epi cut to remove portions of the epi, resulting in an exposed two or more sides of the epi. The method may also include depositing metal contact around the two or more sides of the epi. The method may also include depositing dielectric to separate portions of the metal contact, resulting in one or more wrapped contacts separated by the dielectric.

The above summary is not intended to describe each illustrated embodiment or every implementation of the present disclosure.

### BRIEF DESCRIPTION OF THE DRAWINGS

The drawings included in the present application are incorporated into, and form part of, the specification. They illustrate embodiments of the present disclosure and, along with the description, serve to explain the principles of the disclosure. The drawings are only illustrative of certain embodiments and do not limit the disclosure.

FIGS. 1A-1C depicts various views of a semiconductor structure with a dielectric bar and wrapped contact, according to some embodiments.

FIGS. 2A-2C depicts various cross-sectional views of a first intermediate step of forming a semiconductor structure, according to some embodiments.

FIGS. 3A-3C depicts various cross-sectional views of a second intermediate step of forming a semiconductor structure, according to some embodiments.

FIGS. 4A-4C depicts various cross-sectional views of a third intermediate step of forming a semiconductor structure, according to some embodiments.

FIGS. 5A-5C depicts various cross-sectional views of a fourth intermediate step of forming a semiconductor structure, according to some embodiments.

FIGS. 6A-6C depicts various cross-sectional views of a fifth intermediate step of forming a semiconductor structure, according to some embodiments.

FIGS. 7A-7C depicts various cross-sectional views of a sixth intermediate step of forming a semiconductor structure, according to some embodiments.

FIGS. 8A-8C depicts various cross-sectional views of a seventh intermediate step of forming a semiconductor structure, according to some embodiments.

FIGS. 9A-9C depicts various cross-sectional views of an eighth intermediate step of forming a semiconductor structure, according to some embodiments.

FIGS. 10A-10C depicts various cross-sectional views of a ninth intermediate step of forming a semiconductor structure, according to some embodiments.

FIGS. 11A-11C depicts various cross-sectional views of a tenth intermediate step of forming a semiconductor structure, according to some embodiments.

FIGS. 12A-12C depicts various cross-sectional views of an eleventh intermediate step of forming a semiconductor structure, according to some embodiments.

FIGS. 13A-13C depicts various cross-sectional views of a twelfth intermediate step of forming a semiconductor structure, according to some embodiments.

FIGS. 14A-14C depicts various cross-sectional views of a thirteenth intermediate step of forming a semiconductor structure, according to some embodiments.

FIGS. 15A-15C depicts various cross-sectional views of a fully formed semiconductor structure with dielectric bars and wrapped contacts, according to some embodiments.

FIG. 16 depicts a flowchart of an example method of forming a semiconductor structure with a dielectric bar and wrapped contact, according to some embodiments.

While the invention is amenable to various modifications and alternative forms, specifics thereof have been shown by way of example in the drawings and will be described in detail. It should be understood, however, that the intention is not to limit the invention to the particular embodiments described. On the contrary, the intention is to cover all modifications, equivalents, and alternatives falling within the spirit and scope of the invention.

### DETAILED DESCRIPTION

Aspects of the present disclosure relate to semiconductors and transistors and, more specifically, to scaled field-effect transistors (FETs) with forksheets/dielectric bars and wrapped contacts. While the present disclosure is not necessarily limited to such applications, various aspects of the disclosure may be appreciated through a discussion of various examples using this context.

Transistors, such as field-effect transistors (FETs), may be used within a system (for example, within a semiconductor) to switch or amplify electric current or voltage. FETs may have two typical configurations, N-channel FETs and P-channel FETs. N-channel FETs introduce (for example, through doping) an n-type impurity to the semiconductor material of the channel between the source and the drain, and P-channel FETs introduce a p-type impurity to the semiconductor material of the channel.

For n-type impurities, arsenic, phosphorous, or any other n-type material may be added to the silicon. N-type materials may have five electrons in their outer orbitals. When the n-type materials are combined with the silicon of the semiconductor, the fifth electron may not have anything to bond to and may freely move around, which may allow an electric current to flow through the silicon semiconductor channel. Because there are extra electrons from the n-type materials, the majority carriers/charge carriers for N-channel FETs are electrons.

In P-channel FETs, p-type impurities such as boron, gallium, etc., may be added to the silicon semiconductor(s) for the silicon doping. The p-type materials may have three electrons in their outer orbitals which, when added to silicon, may form holes (i.e., may lack electrons) in the valence bonds of the silicon atoms. Because there are holes in the valence bonds due to the p-type materials, the majority carriers/charge carriers for P-channel FETs are holes. An N-channel FET may be referred to herein as an NFET and a P-channel FET may be referred to herein as a PFET.

In some instances, it may be beneficial to have multiple FETs connected to each other. For example, in logic gate designs, an N-gate from an NFET may be electrically connected to a P-gate from a PFET in order to form an input for the logic gate. A logic gate may be a circuit with one or more inputs (for example, any number of inputs), but only one output. In some instances, for example, combining NFET and PFET in a logic gate design can eliminate large current leakage from VDD (a positive supply voltage) to ground in a static/non-switching period, as one of the transistors will be off which may prevent different shorts between VDD and ground. This design is conventionally referred to as a complementary metal-oxide-semiconductor (CMOS) logic design. Because of the benefits of combining NFET and PFET in a logic gate design, various logic designs may include NFET-PFET pairs.

As technology has advanced, it has become increasingly beneficial to have large amounts of technology and components in very small spaces. Reducing the size of the technology and components may be referred to herein as scaling. One method of scaling to help fit components in a small area, without reducing the capabilities of the components, is to stack transistors. Stacking transistors may increase the height of the semiconductor chip, but may reduce the area on the chip taken up by transistors. This may help allow for more components on the surface of a chip or may allow for a smaller chip, in some instances. However, for conventional stacked transistors and/or stacked FETs, scaling may be impacted, for example by the contacts needed to connect a source/drain (S/D) with a backside contact or interconnect or an S/D with a frontside contact or interconnect. In conventional stacked FETs, it may be necessary to have separation between various components of the transistors (for example, the contacts, interconnects, PFETs, NFETs, etc.) to prevent unwanted current and/or heat transfer between components. This may make it difficult for scaling and reducing the size of semiconductors/devices. For example, there may be a necessary physical separation/distance needed between an NFET and a PFET in order to help prevent unwanted current and/or heat transfer between the NFET and PFET, device shorts, etc.

In some instances, forksheets (i.e., isolation bars), also referred to herein as dielectric bars, may be used to help create electrical and/or current separation between various components (for example, contacts, interconnects, PFETs, NFETs, etc.) of a semiconductor and/or device while also reducing the physical distance/space needed between components. A forksheet/dielectric bar may help prevent current and/or heat transfer between components (such as the NFET and PFET) due to the material(s) of the dielectric bar. In addition, a dielectric bar may allow the various components to be closer in physical location (i.e., less physically separated), as the dielectric bar is separating/isolating the components, as opposed to needing physical space to separate/isolate components.

However, when a device/semiconductor has dielectric bar(s), S/D resistance may be a concern (for example, the resistance due to the potential height (when viewing from the cross-sections depicted in the figures) of the stacked transistors). For instance, in a nanosheet FET with a dielectric bar, multiple nanosheets may be stacked above/below each other (in some instances, with dielectric between each nanosheet) in order to help scale the device (as the multiple nanosheets may only take up the space of a single nanosheet on the base of the device/chip, therefore the size/area of the base of the device can be small/scaled). In order for the FET(s) to properly function, current and/or charge may need to travel through the S/D regions as well as between the S/D regions (e.g., along all of the stacked nanosheets). However, due to the resistance from the height of the stacked nanosheets, it may be difficult for current and/or charge to travel through the stacked nanosheet FET(s). Put differently, a dielectric bar may allow for more nanosheets to be stacked/in a nanosheet stack than a conventional nanosheet (as there is less space needed between components due to the dielectric bar), however the more stacked nanosheets and/or transistors, the more distance current and/or charge may need to travel, and the higher the resistance of the S/D region.

The present disclosure relates to semiconductors and transistors and, more specifically, to dielectric bars and wrapped contacts in stacked FETs. As discussed herein, dielectric bars can help improve scaling and decrease the size of the semiconductors and transistors, particularly the portions of the components (such as the base(s) of the components) attached to the substrate and/or chip, as dielectric bars may allow for components to be in closer proximity to each other due to the isolation created by the dielectric bars. Therefore, dielectric bar(s) may be desired to help decrease the size of a device and/or semiconductor chip and its components.

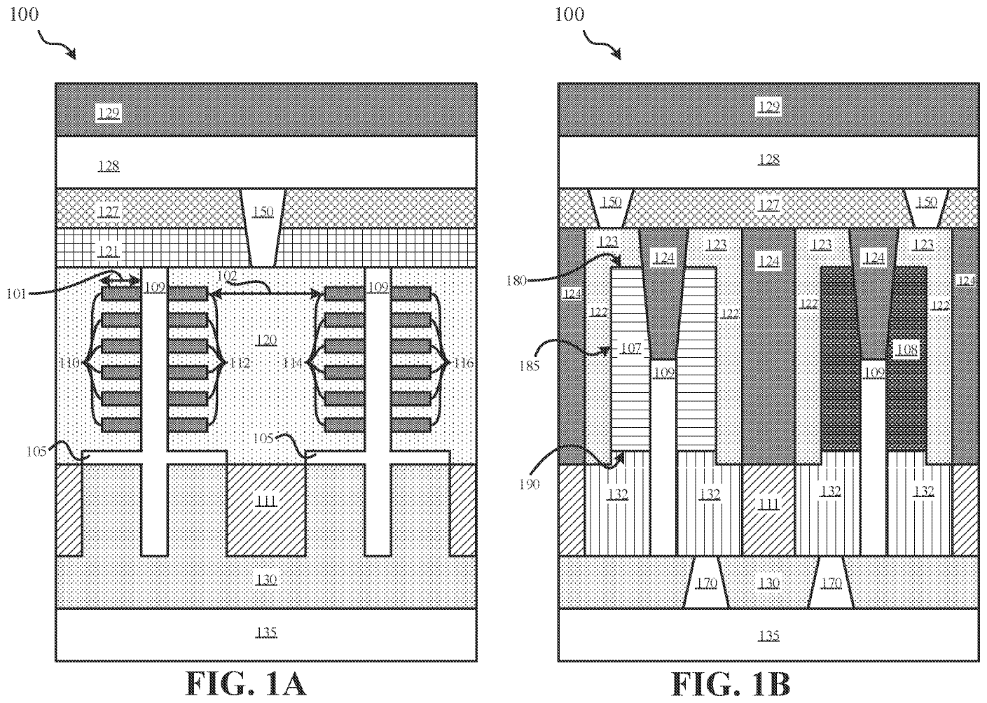

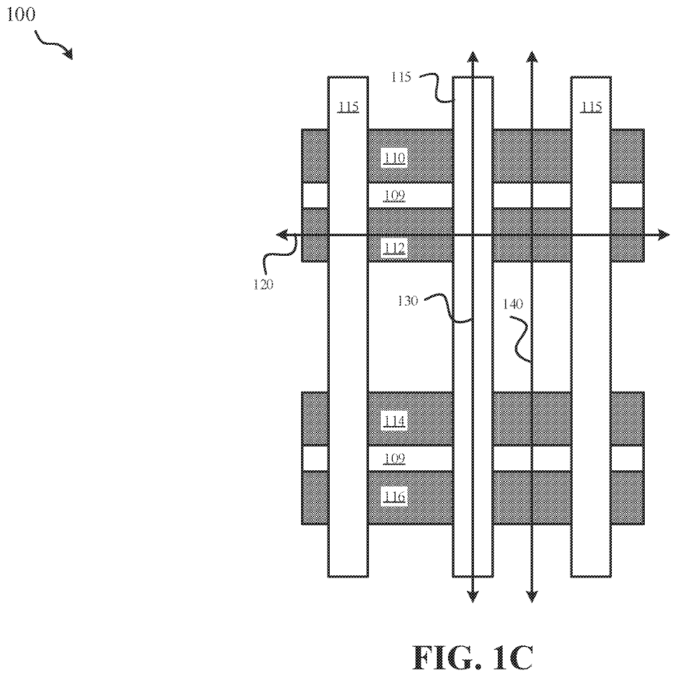

However, S/D resistance may cause issues and prevent additional scaling of the device/semiconductor, as it may be difficult for current and/or charge to fully travel through the desired portions of the transistors, particularly as more and more transistors (such as nanosheets) are stacked above/below of each other. Below, above, on top of, etc. may refer to components (such as transistors) and their positions when looking at a cross-sectional view such as the views depicted in FIGS. 1-15C.

To help reduce and/or eliminate any issues due to the S/D resistance, while also allowing for additional scaling, stacked FETs with dielectric bars and wrapped contacts are discussed herein. The wrapped contacts may be contacts that wrap around multiple portions and/or sides of the S/D epitaxy (epi). In some instances, the wrapped contacts may be connected to a plurality of sides (for example, top, sidewall, and bottom portions) of the S/D epis (for instance, when viewing from the cross-sections depicted in FIGS. 1-15C). Put differently, the wrapped contacts may have frontside contact, sidewall contact, and backside contact with the epis. By having a wrapped contact with multiple points of contact with the epi, current can access and travel through the entire epi, even with the S/D resistance, as the wrapped contact has direct contact with multiple portions and/or sides of the epi.

According to an aspect of the invention, there is provided a semiconductor structure, where the semiconductor structure includes a first transistor, where the first transistor includes an epi, a dielectric bar, and a wrapped contact, where the wrapped contact has direct contact with three or more sides of the epi. In some instances, the use of a dielectric bar can serve to create electrical and/or current separation between components of a semiconductor and can serve to reduce physical distance/space needed between components (i.e., improve scaling of the semiconductor structure). In some instances, the use of a wrapped contact (for instance, with direct contact to two or more sides of the epi) can serve to ensure that current can access and travel through the entire epi, even with S/D resistance, therefore improving the functioning of the semiconductor structure.

In some embodiments, the direct contact with three or more sides of the epi includes direct contact with a bottom side of the epi. This can serve as a point of contact between the wrapped contact and the epi, therefore helping ensure that current can access and travel through the epi.

In some embodiments, the direct contact with three or more sides of the epi further includes direct contact with a top side and one or more sidewalls of the epi. This can serve to connect other contacts (for example, a frontside via contact) with multiple sides of the epi, therefore helping ensure that current can access and travel through the epi.

In some embodiments, a first width of a backside portion of the wrapped contact is greater than a second width of the epi. This can help with direct contact between portions of the wrapped contact, which may help ensure that current can access and travel through the epi.

In some embodiments, a first height of the dielectric bar in a source/drain region of the semiconductor structure is less than a second height of the dielectric bar in a gate region of the semiconductor structure. This may help with the formation of the dummy gate and/or gate region of the semiconductor structure.

In some embodiments, the first transistor further includes stacked nanosheets and a width between the dielectric bar and an end of the stacked nanosheets is a minimum of 6 nanometers and a maximum of 30 nanometers. This can serve to reduce the space between the nanosheets and various components of the semiconductor structure. This can also serve to reduce the size of the nanosheets themselves, in some instances, further helping improve scaling of the semiconductor structure. Further, the small size of the nanosheets may result in nanosheets with smaller sizes/widths than conventional nanosheets, thus improving the scaling of the semiconductor structure.

In some embodiments, the semiconductor structure further includes a second transistor, where the first transistor is an NFET and the second transistor is a PFET. This can serve to form a NFET and PFET pair within the semiconductor structure.

In some embodiments, NFET to PFET (N2P) space between the first transistor and the second transistor is a minimum of 25 nanometers and a maximum of 70 nanometers. This may result in a semiconductor structure with smaller N2P space than conventional nanosheets, thus improving the scaling and reducing the size of the semiconductor structure.

According to an aspect of the invention, there is provided a system, where the system includes a semiconductor structure, where the semiconductor structure includes a first transistor, where the first transistor includes an epi, stacked nanosheets, a dielectric bar, where the dielectric bar is directly connected to the stacked nanosheets, and a wrapped contact, where the wrapped contact has direct contact with three or more sides of the epi. In some instances, the use of a dielectric bar can serve to create electrical and/or current separation between components of a semiconductor and can serve to reduce physical distance/space needed between components (i.e., improve scaling of the semiconductor structure). In some instances, the use of a wrapped contact (for instance, with direct contact with two or more sides of the epi) can serve to ensure that current can access and travel through the entire epi, even with S/D resistance, therefore improving the functioning of the semiconductor structure.

In some embodiments, the direct contact with three or more sides of the epi includes direct contact with a bottom side of the epi. This can serve as a point of contact between the wrapped contact and the epi, therefore helping ensure that current can access and travel through the epi.

In some embodiments, the direct contact with three or more sides of the epi further includes direct contact with a top side and one or more sidewalls of the epi. This can serve to connect other contacts (for example, a frontside via contact) with multiple sides of the epi, therefore helping ensure that current can access and travel through the epi.

In some embodiments, a first width between the dielectric bar and an end of the stacked nanosheets is less than a second width between the dielectric bar and shallow trench isolation. This can serve to reduce the space between the nanosheets and various components of the semiconductor structure. This can also serve to reduce the size of the nanosheets themselves, in some instances, further helping improve scaling of the semiconductor structure. Further, the small size of the nanosheets may result in nanosheets with smaller sizes/widths than conventional nanosheets, thus improving the scaling of the semiconductor structure.

In some embodiments, the system further includes a second transistor, where the second transistor is a same type as the first transistor, and where the second transistor includes a second set of stacked nanosheets. In some embodiments, the dielectric bar is directly connected to the second set of stacked nanosheets. In some embodiments, the second transistor further includes a second epi, where the epi and the second epi are separated by the dielectric bar and dielectric. This can serve to help improve scaling of the semiconductor structure, as multiple transistors may be close together and may not need much, if any, space between transistors.

According to an aspect of the invention, there is provided a method of forming a semiconductor structure, the method including forming a set of stacked nanosheets; forming a dielectric bar, where the dielectric bar is directly connected to the set of stacked nanosheets; growing an epi; performing an epi cut to remove portions of the epi, resulting in an exposed two or more sides of the epi; depositing metal contact around the two or more sides of the epi; and depositing dielectric to separate portions of the metal contact, resulting in one or more wrapped contacts separated by the dielectric. In some instances, the formation/use of a dielectric bar can serve to create electrical and/or current separation between components of a semiconductor structure and can serve to reduce physical distance/space needed between components (i.e., improve scaling of the semiconductor structure). In some instances, the formation/use of a wrapped contact (for instance, with a plurality of portions of contact to the epi) can serve to ensure that current can access and travel through the entire epi, even with S/D resistance, therefore improving the functioning of the semiconductor structure.

In some embodiments, the two or more sides include a top side and a sidewall of the epi. This can serve to connect other contacts (for example, a frontside via contact) with multiple sides of the epi, therefore helping ensure that current can access and travel through the epi.

In some embodiments, the method further includes removing a contact placeholder, resulting in an exposed bottom side of the epi; and depositing a backside contact along the exposed bottom side of the epi, where the backside contact is directly connected to the bottom side of the epi and the metal contact, and where the one or more wrapped contacts include the metal contact and the backside contact. This can serve to connect other contacts (for example, a frontside via contact and/or backside via contact) with multiple portions of the epi, therefore helping ensure that current can access and travel through the epi.

In some embodiments, the method further includes cutting portions of the metal contact, where the dielectric is deposited subsequent to the cutting. This can serve to remove any excess metal and help separate the epi from any unwanted connections.

In some embodiments, the method further includes trimming the set of stacked nanosheets. In some embodiments, trimming the set of stacked nanosheets reduces a width between the dielectric bar and an end of the stacked nanosheets. This can serve to reduce the size/width of the nanosheets, thus improving the scaling of the semiconductor structure.

Aspects of the present disclosure can be implemented in the technical use case of semiconductor chips and transistors (for example, field-effect transistors (FETs)).

Referring now to FIGS. 1A-1B, various cross-sectional views of a semiconductor structure 100 with a dielectric bar and wrapped contact are depicted, according to some embodiments. FIG. 1A depicts a first cross-sectional view (for example, along a gate region of the semiconductor structure 100) and FIG. 1B depicts a second cross-sectional view (for example, in a source/drain (S/D) region of the semiconductor structure 100), parallel to the first cross-sectional view of semiconductor structure 100. As discussed further herein, FIG. 1A is the cross-sectional view from cross-section 130 (depicted in FIG. 1C) and FIG. 1B is the cross-sectional view from cross-section 140 (depicted in FIG. 1C).

Semiconductor structure 100 includes a backside interconnect 135 with backside via contacts 170 (also referred to herein as backside contacts 170) directly connected to the backside interconnect 135, as well as a frontside interconnect 128 with frontside via contacts 150 (also referred to herein as frontside contacts 150) directly connected to the frontside interconnect 128. In some instances, backside interconnect 135 and frontside interconnect 128 may be back end of line (BEOL) interconnects. Frontside and backside, as referred to herein, may refer to the frontside and backside of a semiconductor die/chip. In some instances, contacts 150 and 170 may be metal contacts, and may be a metal material such as cobalt (Co), tungsten (W), copper (Cu), ruthenium (Ru), etc.

Semiconductor structure 100 may also include a carrier wafer 129 on top of (when viewing from the cross-sections depicted in FIGS. 1A and 1B) the frontside interconnect 128. In some instances, as depicted in FIGS. 1A and 1B, semiconductor structure 100 includes interlayer dielectric(s) (ILD(s)) 127 and 130. In some instances, ILDs 127 and 130 may be dielectric materials such as silicon nitride (SiN), silicon dioxide (SiO₂), other oxide(s), silicoboron carbonitride (SiBCN), silicon oxycarbonitride (SiOCN), silicon carbide (SiC), silicon oxycarbide (SiOC), etc. In some instances, ILDs 127 and 130 may be the same material(s). In some instances, ILDs 127 and 130 may be different materials. Semiconductor structure 100 may include cap 121, in some instances. Cap 121 may be a protective layer to help protect various components of the semiconductor structure 100. In some instances, cap 121 is a dielectric material such as SiN, SiO₂, etc.

Semiconductor structure 100 includes stacked nanosheets 110, 112, 114, and 116. In some instances, the nanosheets 110, 112, 114, and 116 may include silicon (Si) (or silicon compound) materials. In some instances, as depicted in FIGS. 1A and 1B, semiconductor structure 100 includes dielectric bars 109 to separate the nanosheets 110, 112, 114, and 116 and various components of the semiconductor structure 100. The dielectric bar(s) 109 may be dielectric material(s) such as SiN, SiO₂, SiBCN, SiOCN, SiC, SiOC, other oxides, etc. In some instances, nanosheets 110 and 112 may correspond to a first transistor and a second transistor (for example, an NFET or PFET) and nanosheets 114 and 116 may correspond to a third transistor and a fourth transistor (for example, an NFET or PFET). In some instances, nanosheets 110 and 112, while corresponding to different transistors, may be a same type of transistor. Similarly, nanosheets 114 and 116, while corresponding to different transistors, may be a same type of transistors. Nanosheets 110/112 and 114/116 may be different types of transistors, in some instances. For example, nanosheets 110 may be a first NFET transistor, nanosheets 112 may be a second NFET transistor, nanosheets 114 may be a first PFET transistor, and nanosheets 116 may be a second PFET transistor. In another example, nanosheets 110 may be a first PFET transistor, nanosheets 112 may be a second PFET transistor, nanosheets 114 may be a first NFET transistor, and nanosheets 116 may be a second NFET transistor. In these instances, dielectric bar 109 may be described as separating nanosheets/nanosheet transistors and/or separating nanosheets corresponding to a same type of transistor. For instance, nanosheets 110 may make up a set of stacked nanosheets for a first transistor of a first type, and may be separated (by dielectric bar 109) from nanosheets 112 that make up a set of stacked nanosheets for a second transistor of a first type. Similarly, nanosheets 114 may make up a set of stacked nanosheets for a third transistor of a second type, and may be separated (by dielectric bar 109) from nanosheets 116 that make up a set of stacked nanosheets for a fourth transistor of a second type.

As depicted in FIG. 1A, semiconductor structure 100 includes metal gate 120 (for example, a high-k metal gate 120). In some instances, metal gate 120 may contain a layer of gate insulator, such as HfO₂, HfSiOx, HfLaOx, HfAlOx, etc., and metal gate material(s), including work function metals, such as TiN, TiAlC, TiC, etc., and conductive metals such as W, Co, tantalum (Ta), titanium (Ti), niobium (Nb), ruthenium (Ru), etc., and/or compounds containing these metal material(s). Semiconductor structure 100 may also include bottom dielectric isolation (BDI) 105, in some instances. In some instances, BDI 105 and dielectric bar 109 may be part of a same structure and may be a same material(s), however they may serve different purposes. For example, as depicted in FIG. 1A, BDI 105 may be a horizontal portion of the dielectric that serves to help isolate various components (for example, the nanosheets 110, 112, 114, 116, and the metal gate 120) from other components of the semiconductor structure 100. Dielectric bar 109 may be a vertical portion of the dielectric that serves to isolate the nanosheets 110, 112, 114, 116, from each other and from other components of the semiconductor structure 100.

Semiconductor structure 100 may also include, in some instances, isolation 111, such as shallow trench isolation (STI). STI 111 may help prevent current leakage and/or heat transfer between various components of the semiconductor structure 100. In some instances, STI 111 may be dielectric material(s) such as SiN, SiO₂, etc.

As discussed herein, FIG. 1B may depict a cross-sectional view in a source/drain (S/D) region of the semiconductor structure 100. Therefore, as depicted in FIG. 1B, semiconductor structure 100 may include a first epi 107 and a second epi 108. In some instances, the first epi 107 and the second epi 108 may correspond to a first type of transistors and a second type of transistors, respectively. For example, the first epi 107 may be an NFET epi (referred to herein as N-epi) and the second epi 108 may be a PFET epi (referred to herein as P-epi). In some instances, when epi 107 is an N-epi and when epi 108 is a P-epi, nanosheets 110 and 112 may each be part of NFETs (for example, a first NFET and a second NFET, respectively) and nanosheets 114 and 116 may each be part of PFETs (for example, a first PFET and a second PFET, respectively). In some instances, epis 107 and 108 may be materials such as silicon germanium (SiGe), silicon (Si), silicon carbide (SiC), etc. In some instances, epi 107 and epi 108 may be different materials. For instance, the epi materials may correspond to a type of transistor (e.g., NFET or PFET). In some instances, PFETs may include epi materials such as boron-doped or gallium-doped SiGe, and NFETs may include epi materials such as phosphorous-doped or arsenic-doped Si or SiC. Therefore, for example, when epi 107 is an N-epi and epi 108 is a P-epi, epi 107 may be phosphorous- or arsenic-doped Si or SiC and epi 108 may be boron- or gallium-doped SiGe. The epis 107/108 have a plurality of sides. For instance, as depicted in FIG. 1B in relation to epi 107, the epis have at least a top side 180, a sidewall 185, and a bottom side 190. In some instances, the epis may have a plurality of sidewalls (e.g., a left sidewall 185 as well as a right sidewall).

In some instances, as depicted in FIG. 1B, semiconductor structure 100 includes contacts 122, 123, and 132. Although contacts 122/123 and 132 are depicted as separate entities in FIG. 1B (for instance, due to their formations at different times) contacts 122, 123, and 132 may together make up wrapped contacts, in some instances. Therefore, in some instances, contacts 122, 123, and 132 may also be referred to herein as wrapped contacts 122, 123, 132. In some instances, contact(s) 122/123 may alone make up wrapped contacts. In some instances, contacts 122, 123, and 132 may be metal material(s), comprising a layer of silicide liner, such as Ti, Ni, NiPt, etc., a layer of adhesion (i.e., an adhesion layer) such as TiN, TaN, etc., and a conductive metal such as W, Co, Ru, etc. Semiconductor structure 100 may include dielectric 124 to help protect and separate various components of the semiconductor structure 100. Dielectric 124 may be dielectric material(s) such as SiN, SiO₂, etc.

As discussed herein, a dielectric bar 109 may help create electrical and/or current separation between various components and may help with scaling (i.e., reducing the physical distance/space needed between components). For instance, in semiconductor structure 100, dielectric bar(s) 109 may help bring the various nanosheets 110, 112, 114, 116 and transistors closer together, thus reducing the space between components. For example, nanosheets 110 and 112 and nanosheets 114 and 116, respectively, may only be separated by the dielectric bar(s) 109 and may not need any other distance/space between the nanosheets. Further, the spacing between transistors/transistor types (for example, an NFET and PFET) and their corresponding nanosheets (for example, 112 and 114, in FIG. 1A) may be reduced. Even a slight reduction in the spacing between transistor types (e.g., an NFET and PFET) may facilitate easier patterning for work function metals (for example, when compared to conventional transistors/semiconductor devices). This spacing/dimension is depicted by dimension 102 in FIG. 1A. Dimension 102 may also be referred to herein as N2P space (i.e., the spacing between an NFET and PFET). In some instances, N2P space 102 may be range from 25 nanometers to 70 nanometers (i.e., a minimum of 25 nanometers and a maximum of 70 nanometers) in semiconductor structure 100.

In addition to the horizontal spacing between components (for instance, when viewing from the cross-sections depicted in FIGS. 1A and 1B), dielectric bar 109 (as well as stacking a larger number of nanosheets (compared to conventional nanosheet transistors) may also help with the scaling/sizing of the nanosheets (110, 112, 114, 116) themselves, specifically their width (when viewing from the cross-sections depicted in FIGS. 1A and 1B). This dimension is depicted as dimension 101 in FIG. 1A and may be referred to herein as Rx dimension 101. Rx dimension 101 may also be described as the width (for instance, when viewing from the cross-section depicted in FIG. 1A) of a nanosheet from the dielectric bar 109 to an end of the nanosheet. Although Rx dimension 101 is only depicted for nanosheets 110, this dimension 101 may be the same for all the nanosheets 110, 112, 114, 116. In some instances, due to dielectric bar(s) 109, Rx dimension 101 may range from 6 nanometers to 30 nanometers (i.e., a minimum of 6 nanometers and a maximum of 30 nanometers) in semiconductor structure 100.

As discussed herein, conventional nanosheet devices, particularly conventional nanosheet devices with a plurality of nanosheets (for example, greater than three nanosheets), may cause concerns with S/D resistance due to the taller transistor stacks (e.g., taller stacks of nanosheets). For instance, in conventional forksheet devices, if a number of nanosheet layers in a stack are greater than three, due to S/D resistance only portions of the S/D epi(s) may be exposed to current travelling through the transistor, and current may not travel through the entire S/D epi(s). This may cause various issues in the functioning of the transistors (e.g., NFET, PFET, etc.) such as high device on-resistance (Ron), etc.

To prevent issues due to S/D resistance, while also allowing for scaling of the semiconductor structure 100 (for example, through at least dimensions 101 and 102), semiconductor structure 100 includes wrapped contacts 122, 123, 132. Wrapped contacts 122, 123, 132 may include a backside portion (132), a sidewall portion (122), and a frontside portion (123). In some instances, as depicted in FIG. 1B, both sidewall portion 122 and frontside portion 123 may be part of a same frontside contact. However, to help distinguish contact areas in relation to the epis 107/108, the sidewall portion 122 of the frontside contact in FIG. 1B is labelled as sidewall portion 122 and the top portion 123 of the frontside contact is labelled as frontside portion 123.

In some instances, backside portion 132 of the wrapped contacts 122, 123, 132 may be in direct contact with backside contacts 170 as well as in direct contact with a bottom side 190, or bottom portion, (when viewing from the cross-section depicted in FIG. 1B) of the S/D epis 107 and 108. Sidewall portion 122 of the wrapped contacts 122, 123, 132 may be in direct contact with the sidewall(s) 185 of the S/D epis 107 and 108 (when viewing from the cross-section depicted in FIG. 1B), and may also be in direct contact with both the frontside (123) and backside (132) portions of the wrapped contacts 122, 123, 132. Frontside portion 123 of the wrapped contacts 122, 123, 132 may be in direct contact with frontside contacts 150 as well as in direct contact with a top side 180, or top portion, (when viewing from the cross-section depicted in FIG. 1B) of the S/D epis 107 and 108. Therefore, backside portion 132 of the wrapped contacts 122, 123, 132 may have direct contact with at least one side, the bottom side 190, of the S/D epi(s) 107 and/or 108; sidewall portion 122 may have direct contact with at least one or two sides, one or more sidewalls 185, of the S/D epi(s) 107 and/or 108; and frontside portion 123 may have direct contact with at least one side, the top side 180, of the S/D epi(s) 107 and/or 108.

In some instances, the portions/areas of contact between the wrapped contacts 122, 123, 132 and the epis 107/108 may be described in relation to the sides of the epis 107/108. For example, when viewing from the cross-section depicted in FIG. 1B, contact 123 may be described as being in direct contact with a first side, or a top side 180, of the epis 107/108. Contact 122 may be described as being in direct contact with a second side, or a sidewall 185, of the epis 107/108. In some instances, contact 122 is in direct contact with a plurality of sides (e.g., both sidewalls 185) of the epis 107/108. Contact 132 may be described as being in direct contact with a third side, or a bottom side, of the epis 107/108. Therefore, in instances where the wrapped contact(s) include contacts 122 and 123, the wrapped contact(s) may have direct contact with at least two sides of the epis 107/108. In some instances, for example when contact 122 is in contact with a plurality of sidewalls 185 of the epis 107/108, the wrapped contact(s) may have direct contact with at least three sides of the epis 107/108. In instances where the wrapped contact(s) include contacts 122, 123, and 132, the wrapped contact(s) may have direct contact with at least three sides of the epis 107/108. For example, in some instances wrapped contact 122, 123, 132 may have direct contact with a top side 180, a sidewall 185, and a bottom side 190 of the epis 107/108. In some instances, the wrapped contact 122, 123, 132 may have direct contact with at least four sides of the epis 107/108 (for example, the top side 180, two sidewalls 185, and a bottom side 190).

In some instances, a wrapped contact (e.g., wrapped contact 122, 123, 132) may be described as having portions, such as one or more sidewall portions, one or more backside portions, and one or more frontside portions. For example, wrapped contact 122, 123, 132 may have a frontside portion 123, a sidewall portion 122, and a backside portion 132. In some instances, frontside portion 123 of the wrapped contact (122, 123, 132) may be in a frontside area of the semiconductor structure 100 and backside portion 132 of the wrapped contact (122, 123, 132) may be in a backside area of the semiconductor structure 100. Sidewall portion 122 of the wrapped contact (122, 123, 132) may be in a sidewall region of the epi(s) 107/108.

Due to the large amounts of contact between the wrapped contacts 122, 123, 132 and the S/D epis 107 and 108 (as the top, bottom, and sidewalls of the S/D epis 107 and 108), current may reach and may travel through the entire S/D epis 107 and 108 (as opposed to only travelling through a portion of the S/D epis) and the resistance in the S/D region of the semiconductor structure 100 may not hinder the current transfer through the S/D epis (due to the multiple contact points between the S/D epis 107, 108 and the wrapped contacts 122, 123, 132). Therefore, semiconductor structure 100 can benefit from the scaling advantages due to the use of dielectric bar(s) 109 and tall nanosheet stack(s) (for example, nanosheets/nanosheet stacks 110, 112, 114, and/or 116), as well as preventing issues caused by S/D resistance.

Further, with the combination of the wrapped contacts 122, 123, 132 and the use of dielectric bar(s) 109, semiconductor structure 100 may have an increased amount of nanosheets/taller nanosheet stacks (110, 112, 114, 116) when compared to conventional stacked nanosheet structures. For example, in conventional nanosheet structures, the S/D resistance may hinder the amount of nanosheets in a stack (i.e., the amount of stacked nanosheets) (as it may be difficult for current to travel through taller stacks of nanosheets and taller corresponding S/D epis), and only a few nanosheets (e.g., 3) may be able to be stacked. In semiconductor structure 100 with wrapped contacts 122, 123, 132, current may easily travel through and reach the S/D epis 107, 108, therefore more nanosheets may be able to be stacked/in a stack (compared to conventional semiconductors). While semiconductor structure 100 may be depicted as including 6 nanosheets in each nanosheet stack (110, 112, 114, 116), this is not intended to limit the number of nanosheets in the nanosheet stacks, and the nanosheets (110, 112, 114, 116) may include other numbers of nanosheets in the stack(s).

Semiconductor structure 100 may be an example structure for stacked FETs (e.g., nanosheets) with forksheets/dielectric bars and wrapped contacts. For example, while semiconductor structure 100 may depict four transistors (e.g., two NFETs and two PFETs), two corresponding dielectric bars 109, two corresponding S/D epis 107 and 108, etc., any number of transistors (and their corresponding components) may be used.

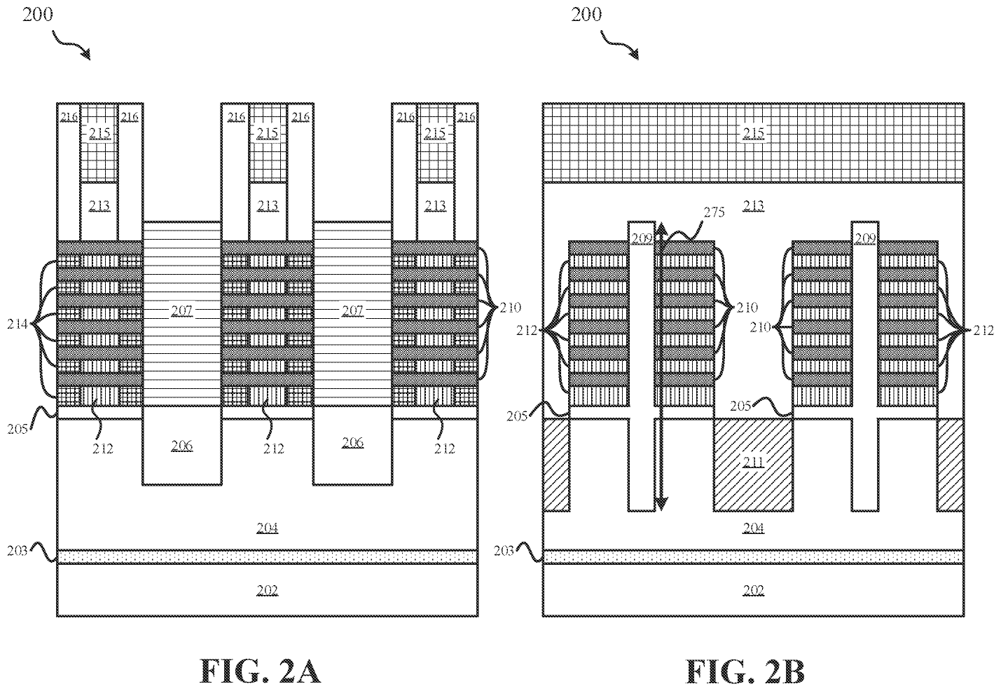

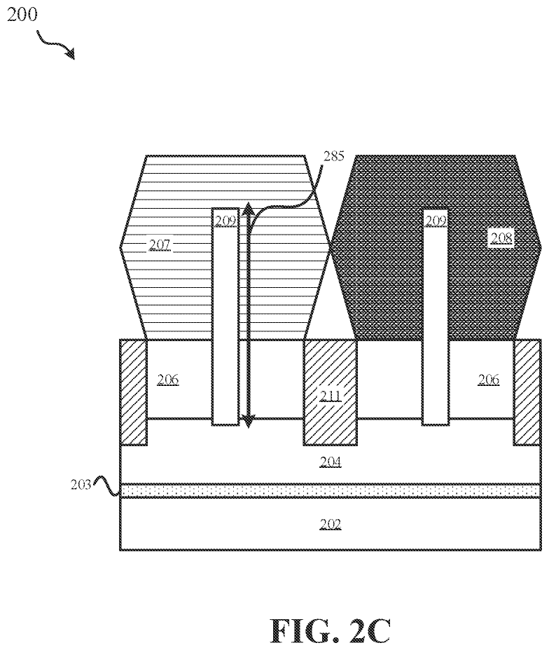

Referring now to FIG. 1C, a top down view of a semiconductor structure 100 with various cross-sections is depicted, according to some embodiments. These cross-sections may be the same/similar cross-sections referenced in FIGS. 1A and B, as well as, in some instances, FIGS. 2A-15C. The top down view of semiconductor structure 100 includes nanosheets 110, 112, 114, and 116, dielectric bars 109, and gate 115. The various cross-sectional views referenced herein (and depicted in FIG. 1C), include an X view 120, a Y1 view 130, and a Y2 view 140. These may also be referred to herein as cross-section X (120), cross-section Y1 (130), and cross-section Y2 (140). In some instances, FIG. 1A may depict a view from cross-section Y1 (130) and FIG. 1B may depict a view from cross-section Y2 (140).

In some instances, FIGS. 2A, 3A, 4A, 5A, 6A, 7A, 8A, 9A, 10A, 11A, 12A, 13A, 14A, and 15A may correspond to an X cross-sectional view similar to cross-section X 120 (FIG. 1C). FIGS. 2B, 3B, 4B, 5B, 6B, 7B, 8B, 9B, 10B, 11B, 12B, 13B, 14B, and 15B may correspond to a Y1 cross-sectional view similar to cross-section Y1 130 (FIG. 1C). FIGS. 2C, 3C, 4C, 5C, 6C, 7C, 8C, 9C, 10C, 11C, 12C, 13C, 14C, and 15C may correspond to a Y2 cross-sectional view similar to cross-section Y2 140 (FIG. 1C).

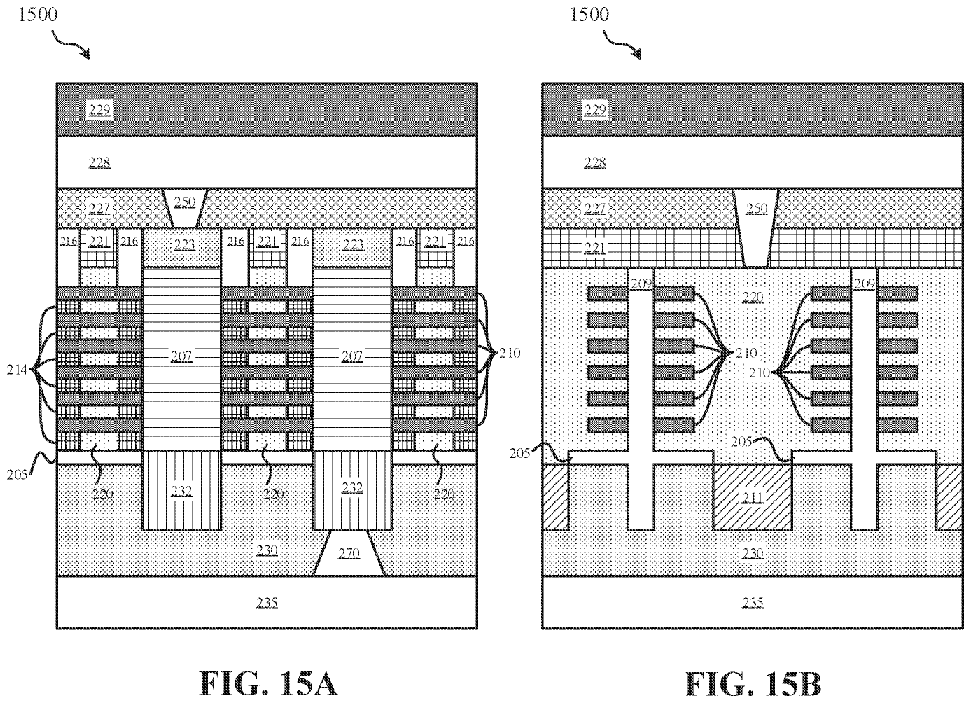

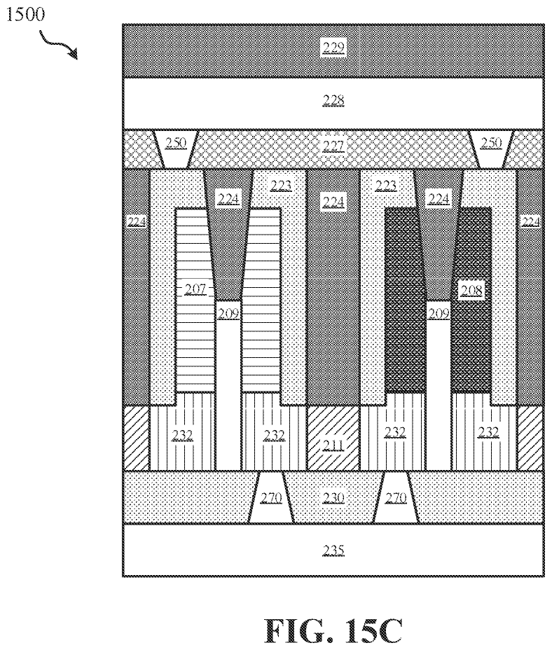

Referring now to FIGS. 2A-15C, FIGS. 2A-14C depict intermediate steps in the process of forming semiconductor structure 1500 (FIGS. 15A-C), according to some embodiments. FIGS. 15A-15C depict the fully formed semiconductor structure 1500 with dielectric bar(s) and wrapped contact(s). Although FIGS. 2A-14C are discussed in relation to semiconductor structure 1500, the same/similar steps may be used to form semiconductor structure 100 (FIG. 1), in some instances.

Referring now to FIGS. 2A-2C, various cross-sectional views of an intermediate structure corresponding to an intermediate step 200 of forming a semiconductor structure are depicted, according to some embodiments. FIG. 2A depicts an X cross-sectional view of intermediate step 200, FIG. 2B depicts a Y1 cross-sectional view of intermediate step 200, and FIG. 2C depicts a Y2 cross-sectional view of intermediate step 200. Intermediate step 200 includes a substrate 202 directly connected to an etch stop layer 203. In some instances, substrate 202 may be a silicon (Si) substrate and/or etch stop layer 203 may be SiGe. Intermediate step 200 may include a second substrate 204 (e.g., a silicon substrate), in some instances. In some instances, substrates 202 and 204 may serve as placeholders for future materials/structures.

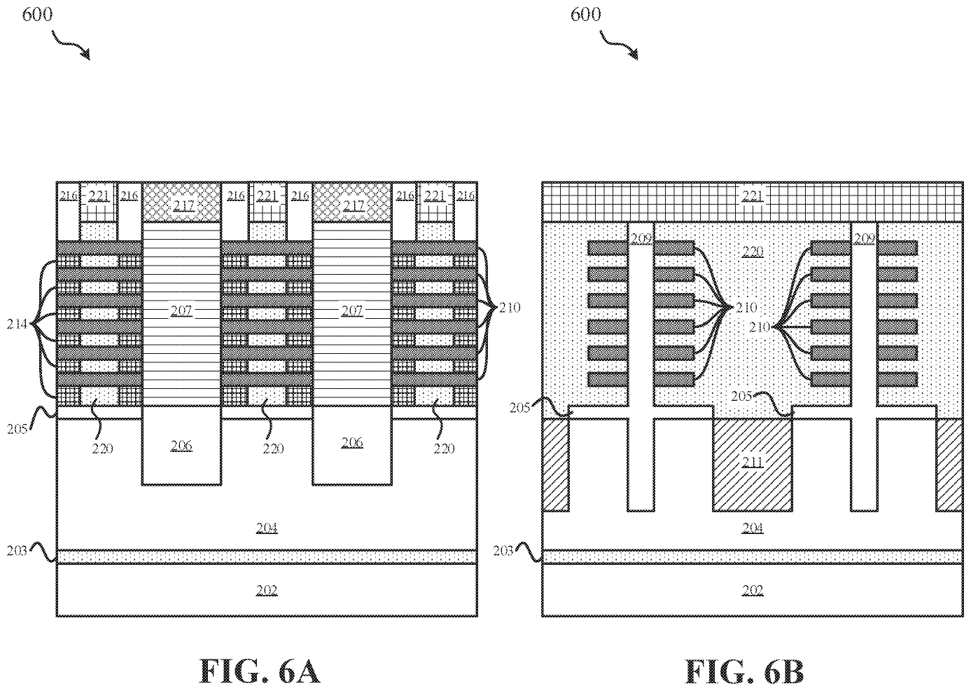

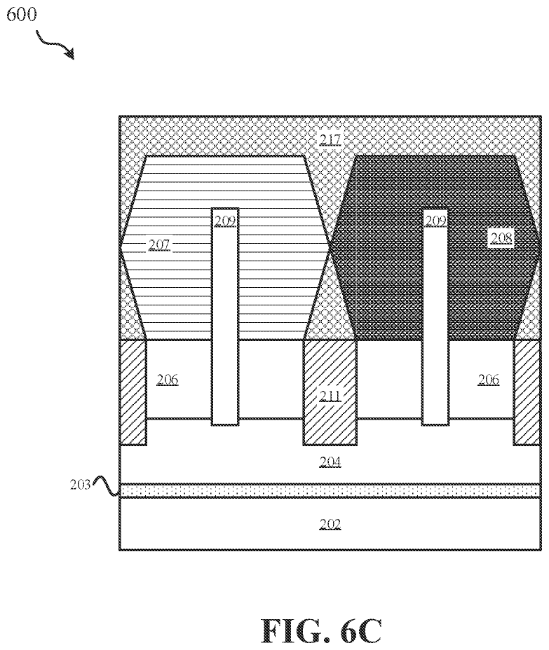

In some instances, as depicted in FIG. 2A, intermediate step 200 may include backside contact placeholders 206 (which may serve as placeholders for later formed backside contacts). In some instances, backside contact placeholders 206 may be dielectric material(s) or semiconductor materials. As depicted in FIG. 2C, Intermediate step 200 may also include S/D epis 207 and 208. In some instances, epi 207 may be an N-epi 207 and epi 208 may be a P-epi 208. Intermediate step 200 also includes nanosheets 210 and sacrificial sheets 212 (e.g., SiGe). In some instances, as depicted in FIGS. 2A and B, the nanosheets 210 and sacrificial sheets 212 may be in alternating layers. In some instances, nanosheets 210 may be referred to as a set of nanosheets 210 and/or a set of stacked nanosheets 210. FIG. 2A also depicts inner spacer(s) 214. Inner spacer(s) 214 may help prevent any unwanted damage to the source/drain (S/D) region during a replacement gate process (for example, intermediate step 600 (FIGS. 6A-C) where a dummy gate 213 is replaced by an actual gate). In some instances, inner spacer 214 may be dielectric material(s) such as SiN, SiO₂, etc.

In some instances, intermediate step 200 includes BDI(s) 205 and dielectric bar(s) 209. BDI(s) 205 and dielectric bar(s) 209 may correspond to BDI(s) 105 and dielectric bar(s) 109 (FIGS. 1A-B), respectively, in some instances. Intermediate step 200 may also include STI 211 (which may correspond to STI 111 (FIGS. 1A and B), in some instances).

In some instances, intermediate step 200 includes dummy gate 213 and hard mask 215. Dummy gate 213 may be used as a placeholder gate until an actual metal gate is formed in a later step (discussed further herein). In some instances, dummy gate 213 is a dielectric material. Hard mask 215 may be used to help protect and prevent any unwanted etching of various components of the intermediate structure.

Intermediate step 200 may also include spacers 216 (depicted in FIG. 2A). Spacers 216 may be used in the process of forming a semiconductor structure (such as semiconductor structure 1500 (FIGS. 15A-C) and/or semiconductor structure 100 (FIGS. 1A-B)) to help achieve the proper and/or necessary placement and spacing between the various components of a semiconductor structure. In some instances, spacers 216 may be material(s) such as silicon boron carbonitride (SiBCN), SiN, silicon oxynitride (SiON), silicon carbonate (SiCO), etc.

FIGS. 2B and 2C depict heights 275 and 285 of the dielectric bar 209 from various regions of the semiconductor structure 200. For instance, height 275 may be the height of the dielectric bar 209 in the gate region of the semiconductor structure 200 (i.e., the region depicted from the Y1 cross-section depicted in FIG. 2B). Height 285 may be the height of the dielectric bar 209 in the S/D region of the semiconductor structure 200 (i.e., the region depicted from the Y2 cross-section depicted in FIG. 2C). In some instances, the height 285 of the dielectric bar 209 in the S/D region of the semiconductor structure (depicted in FIG. 2C) is lower (i.e., less than) the height 275 of the dielectric bar 209 in the gate region of the semiconductor structure (depicted in FIG. 2B). This may be because the process of forming of the dummy gate 213, inner spacer 214, and/or S/D epis 207/208 may also etch the dielectric bar 209 in the S/D region (FIG. 2C) (as the dielectric bar 209 in the gate region (FIG. 2B) is buried inside/surrounded by dummy gate 213, which prevents the dielectric bar 209 in the gate region (FIG. 2B) from being etched), causing the dielectric bar 209 in the S/D region (FIG. 2C) to have a lower/lesser height 285 than the height 275 of the dielectric bar 209 in the gate region (FIG. 2B).

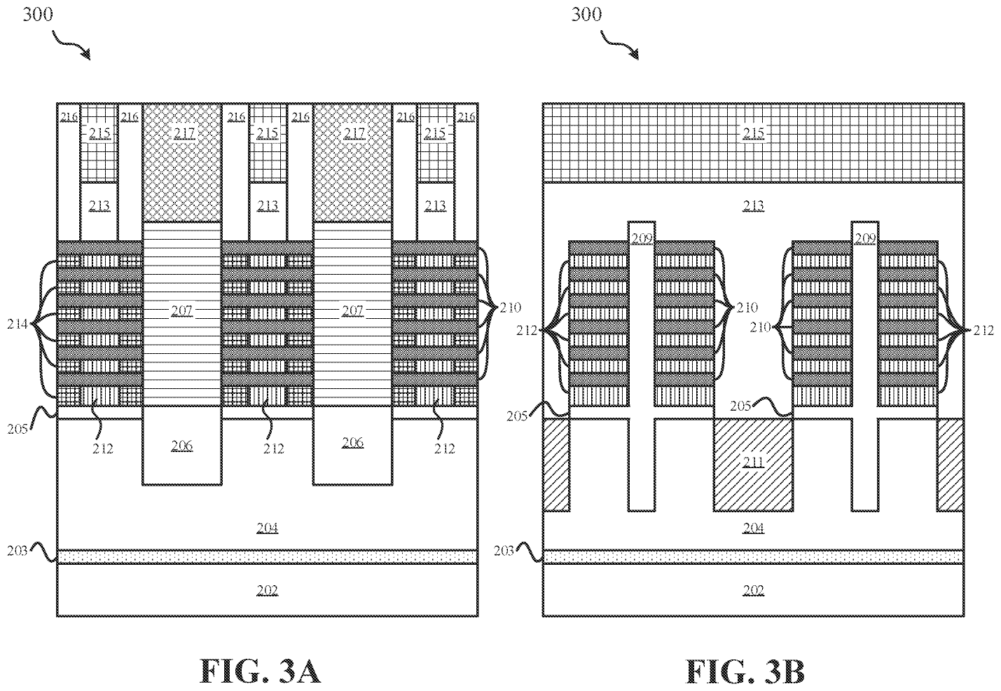

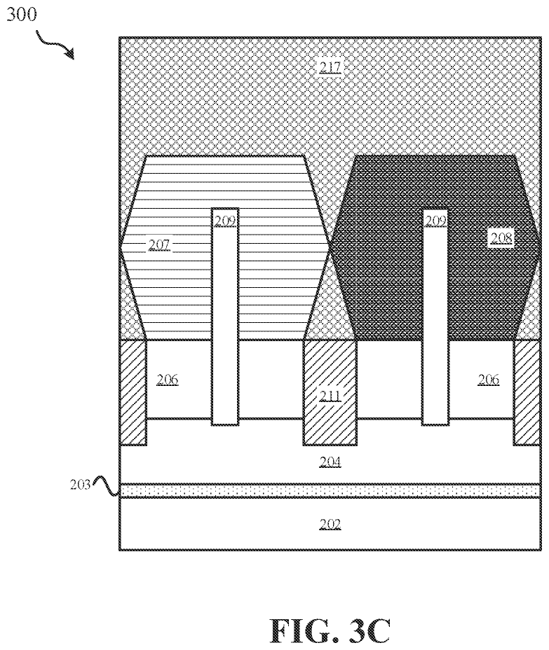

Referring to FIGS. 3A-3C, various cross-sectional views of an intermediate structure corresponding to an intermediate step 300 of forming a semiconductor structure are depicted, according to some embodiments. In intermediate step 300, ILD 217 is deposited (also referred to herein as an ILD fill). In some instances, ILD 217 is deposited/filled through methods such as atomic layer deposition (ALD), chemical vapor deposition (CVD), laser induced chemical vapor deposition (LCVD), and/or any other deposition technique. In some instances, intermediate step 300 further includes chemical mechanical planarization (CMP) to smooth/polish the ILD 217.

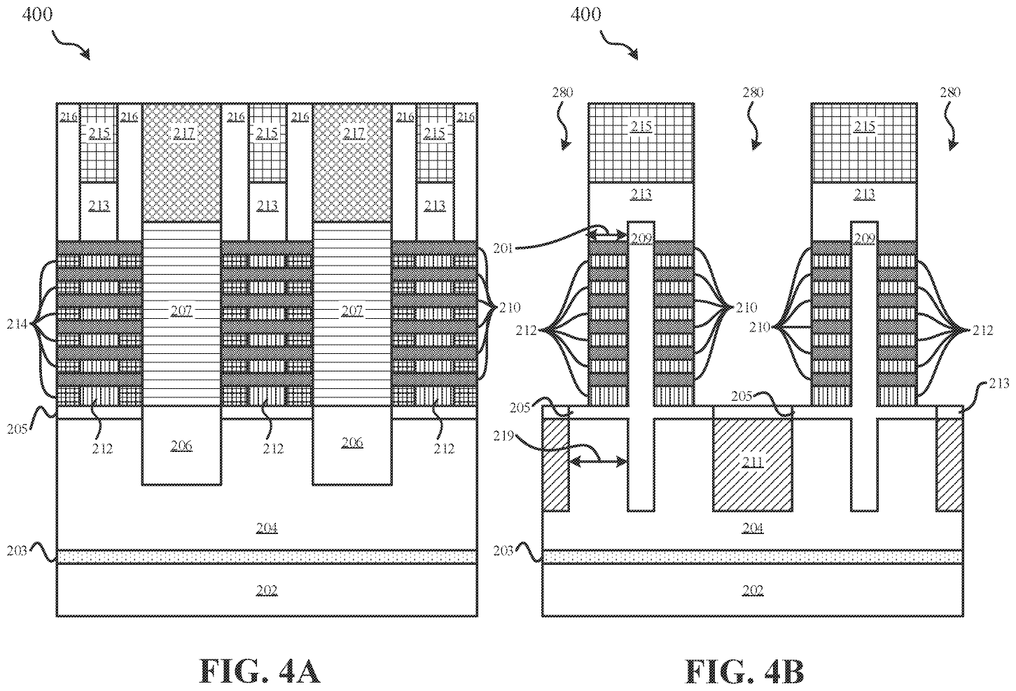

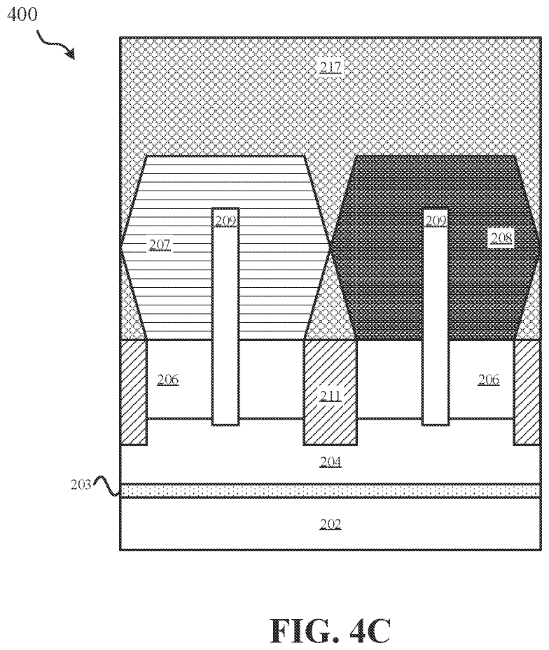

Referring to FIGS. 4A-4C, various cross-sectional views of an intermediate structure corresponding to an intermediate step 400 of forming a semiconductor structure are depicted, according to some embodiments. In intermediate step 400, channel cuts/openings 280 are made. Put differently, portions of the nanosheets 210, sacrificial sheets 212, dummy gate 213, and hard mask 215 are removed/etched in order to form channel cuts/openings 280. In some instances, although the openings 280 are depicted in FIG. 4B as straight vertical openings, the openings 280 may be slightly tapered. The channel cuts 280 may be made using the etching/removing may be done using reactive ion etching (RIE), ion beam etching (IBE), or any other patterning/etching process, in some instances.

In some instances, as depicted in FIG. 4B, forming the channel cuts 280 may include trimming/removing excess portions of nanosheets 210 and sacrificial sheets 212. For instance, when the nanosheets 210 and sacrificial sheets 212 are originally formed/deposited, they may be deposited in a wider shape (i.e., with excess width) than desired. After the channel cuts 280, dimension 201 (for example, the Rx dimension (in some instances, corresponding to Rx dimension 101 (FIG. 1A)) may be the desired width/dimension 201 for the semiconductor structure. In some instances, the width between the dielectric bar 209 and an end of the nanosheets 210 (i.e., width/dimension 201) is less than a width between the dielectric bar 209 and STI 211 (depicted in FIG. 4B as width/dimension 219). This may be because of the channel cuts 280 reducing the width (201) of the nanosheets 210.

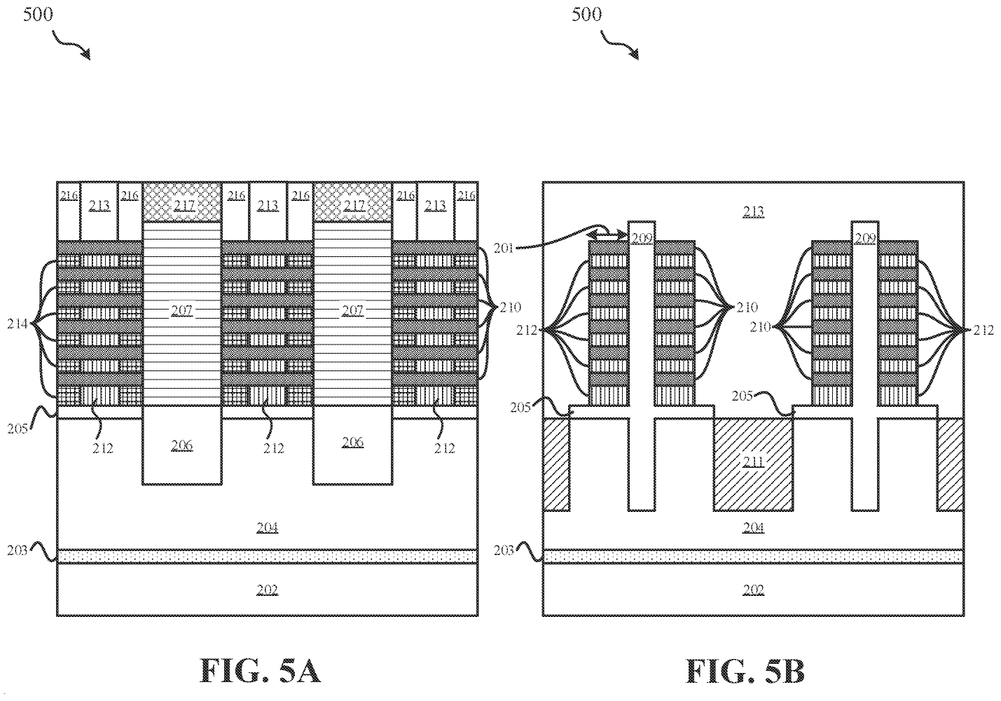

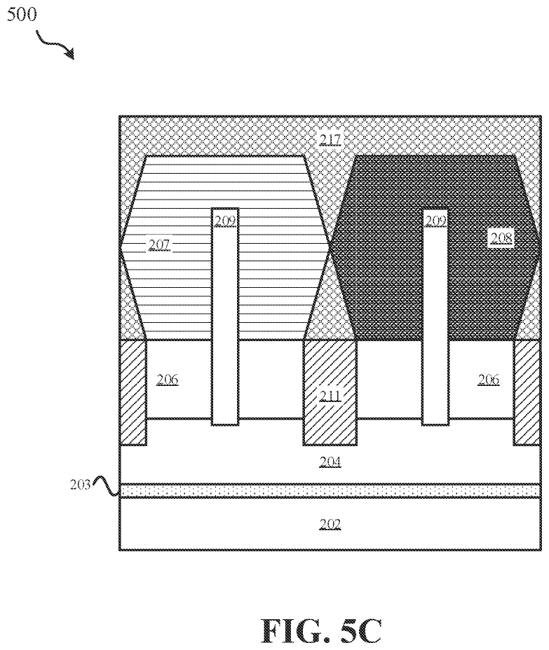

Referring to FIGS. 5A-5C, various cross-sectional views of an intermediate structure corresponding to an intermediate step 500 of forming a semiconductor structure are depicted, according to some embodiments. Intermediate step 500 may include removing the remaining portions of the hard mask 215 and filling the channel cuts 280 with additional dummy gate 213 fill. By performing the channel cuts 280 in intermediate step 400 (FIGS. 4A-4C), the sacrificial sheets 212 and the nanosheets 210 were able to be trimmed to their desired dimension 201. However, after the channel cuts 280 are formed, additionally dummy gate 213 may be filled in order to continue serving as a placeholder gate until an actual metal gate is formed. In some instances, the dummy gate 213 may be deposited/filled through methods such as ALD, CVD, LCVD, and/or any other deposition technique. In some instances, after the additional dummy gate 213 is deposited/filled, a poly open CMP (POC) may be performed to smooth/polish the top surface of the dummy gate 213 (when viewing from the cross sections depicted in intermediate step 500).

Referring to FIGS. 6A-6C, various cross-sectional views of an intermediate structure corresponding to an intermediate step 600 of forming a semiconductor structure are depicted, according to some embodiments. In some instances, intermediate step 600 includes forming gate 220. To form gate 220, the dummy gate 213 and the sacrificial sheets 212 may be removed. In some instances, the dummy gate 213 may be removed/etched using a selective wet etch or dry etch process. In some instances, as discussed herein, sacrificial sheets 212 may be SiGe. This way, sacrificial sheets 212 may be removed without removing any other materials/components of the semiconductor structure, as the removal process(es) can be tailored to the SiGe (and even to a specific germanium content, in some instances).

Once the dummy gate 213 and the sacrificial sheets 212 are removed, a metal gate fill (for example, a high-k metal gate fill) may be performed in order to form metal gate 220. Put differently, the open spaces left after the removal of the dummy gate 213 and the sacrificial sheets 212 may be filled with a metal gate material(s) (for example, a high-k dielectric and metal material(s)). The metal gate material(s) may be referred to herein as metal gate 220. In some instances, metal gate 220 is a high-k metal gate. In some instances, the metal gate 220 may be filled/deposited using methods such as ALD, CVD, LCVD, and/or any other deposition technique. In some instances, metal gate 220 may contain some combination of gate insulator (such as HfO₂, HfSiOx, HfLaOx, HfAlOx, etc.) and metal material(s), including work function metals (such as TIN, TiAlC, TiC, etc.) and/or conductive metals (such as W, Co, tantalum (Ta), titanium (Ti), niobium (Nb), ruthenium (Ru), etc.).

In some instances, intermediate step 600 further includes recessing the metal gate 220 and depositing cap 221. In some instances, cap 221 may be directly connected to metal gate 220, and may be a protective layer to help protect the metal gate 220 and various components of the semiconductor structure. In some instances, cap 221 is a dielectric material such as SiN, SiO₂, etc.

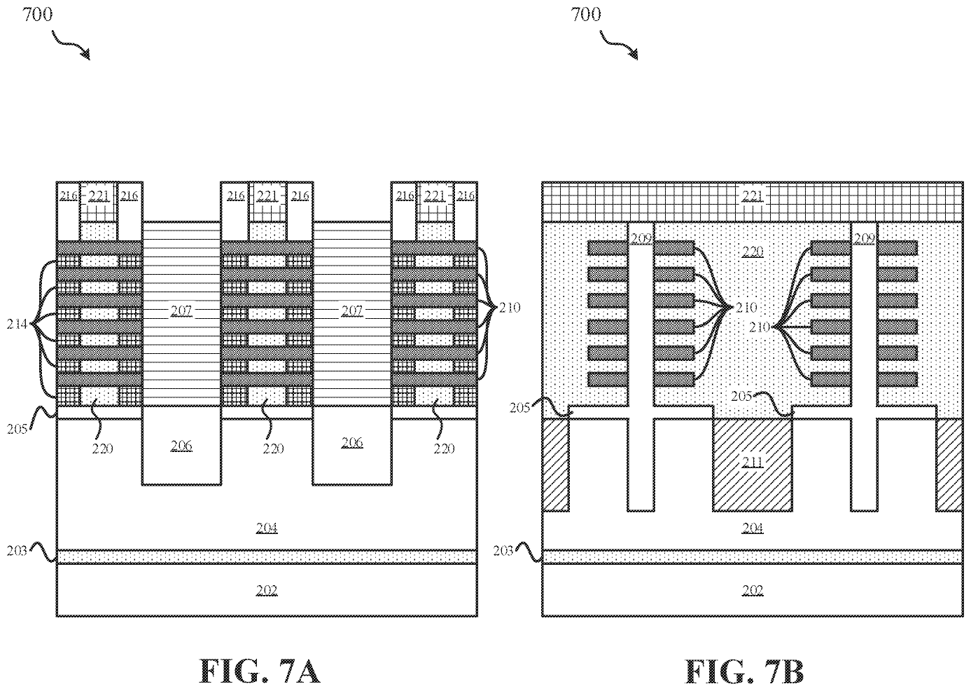

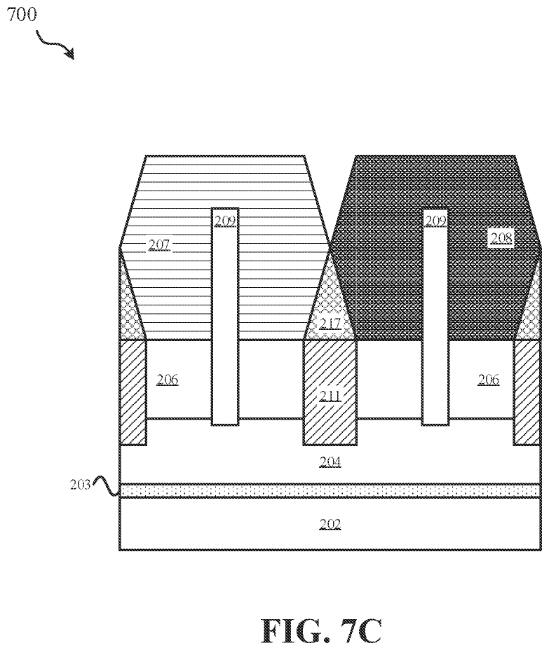

Referring to FIGS. 7A-7C, various cross-sectional views of an intermediate structure corresponding to an intermediate step 700 of forming a semiconductor structure are depicted, according to some embodiments. In some instances, intermediate step 700 includes recessing ILD 217. Specifically, as depicted in FIGS. 7A and 7C, portions of ILD 217 above (when viewing from the cross-sections depicted in FIGS. 7A-C) the widest points of the epis 207 and 208 may be removed/recessed. This way, excess ILD 217 above the epis 207 and 208 is removed before any additional cuts/etches are made. In some instances, the recessing/etching/removing may be done using RIE, IBE, or any other etching process.

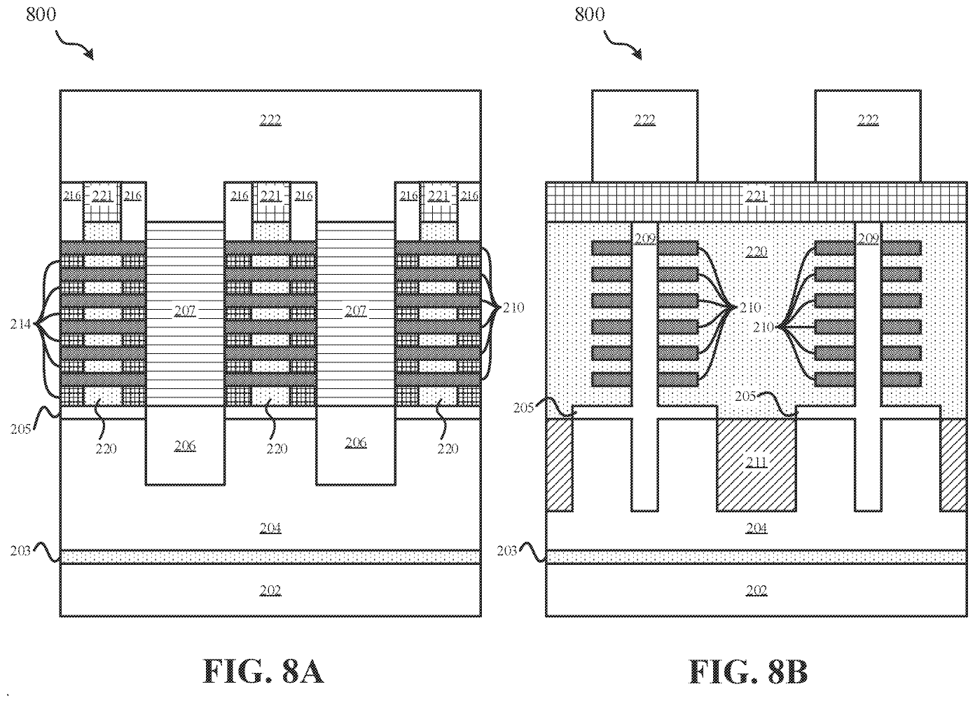

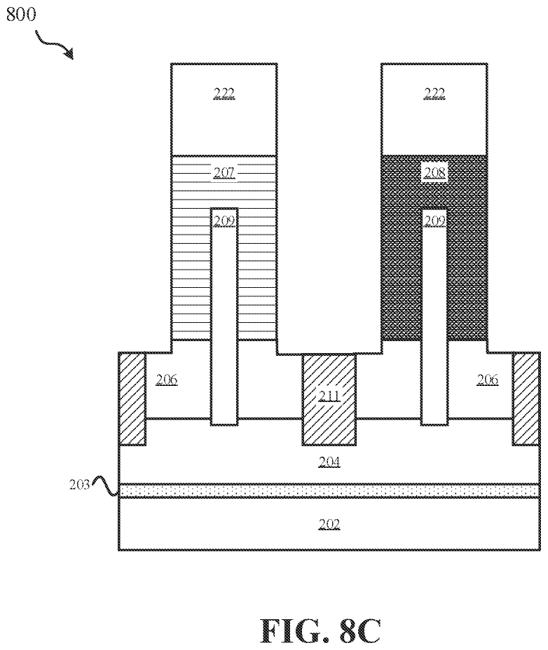

Referring to FIGS. 8A-8C, various cross-sectional views of an intermediate structure corresponding to an intermediate step 800 of forming a semiconductor structure are depicted, according to some embodiments. Intermediate step 800 may include performing an epi cut. Prior to an epi cut, a mask such as an organic planarization layer (OPL) 222 may be deposited (for example, through ALD, CVD, LCVD, and/or any other deposition technique). OPL 222 may protect various components (such as the nanosheets 210 and the dielectric bar 209) from any unwanted etching. Once any necessary components are protected, intermediate step 800 may include performing an epi cut to remove excess portions of the epis 207 and 208. The epi cut may go through portions of the OPL 222, in some instances. In some instances, the epi cut/removal may be done using RIE, IBE, or any other etching process.

In some instances, as depicted in FIGS. 2A-8C, portions of epis 207 and 208 may have been touching/in direct contact with each other. However, in the fully formed semiconductor structure (for example semiconductor structure 100 (FIGS. 1A-B) and/or semiconductor structure 1500 (FIGS. 15A-15C)), it may not be desired to have epis 207 and 208 in direct contact with each other. Therefore, the epi cut may remove excess portions of epis 207 and 208, and may separate the epis 207 and 208 so that they are not in direct contact with each other. Further, as discussed herein, the fully formed semiconductor structure (for example semiconductor structure 100 (FIGS. 1A-B) and/or semiconductor structure 1500 (FIGS. 15A-15C)) may include wrapped contacts that have multiple areas of contact with the epis 207 and 208. The epi cut in intermediate step 800 may expose sidewalls of the epis 207 and 208 and may make space for wrapped contacts to be formed in direct contact with the sidewalls of the epis 207 and 208. For instance, the epi cut may expose the sidewall surface(s) of the epis 207/208 so that contact(s) 223 (discussed further herein) may be formed directly connected to the sidewall(s) of the epis 207/208. In some instances, the epi cut may further reduce the size of the epis 207/208 such that the size (for example, the width, when looking from the cross-section depicted in FIG. 8C) of the epis 207/208 is smaller than the size/width of the backside contact placeholder 206. This way, the later formed backside contact 132 (discussed herein) can directly connect to contact 223 (e.g., the sidewall portion of contact 223). In some instances, although intermediate step 800 is depicted as having a vertical/straight epi cut, the epi cut may not be fully vertical and instead may be slightly tapered.

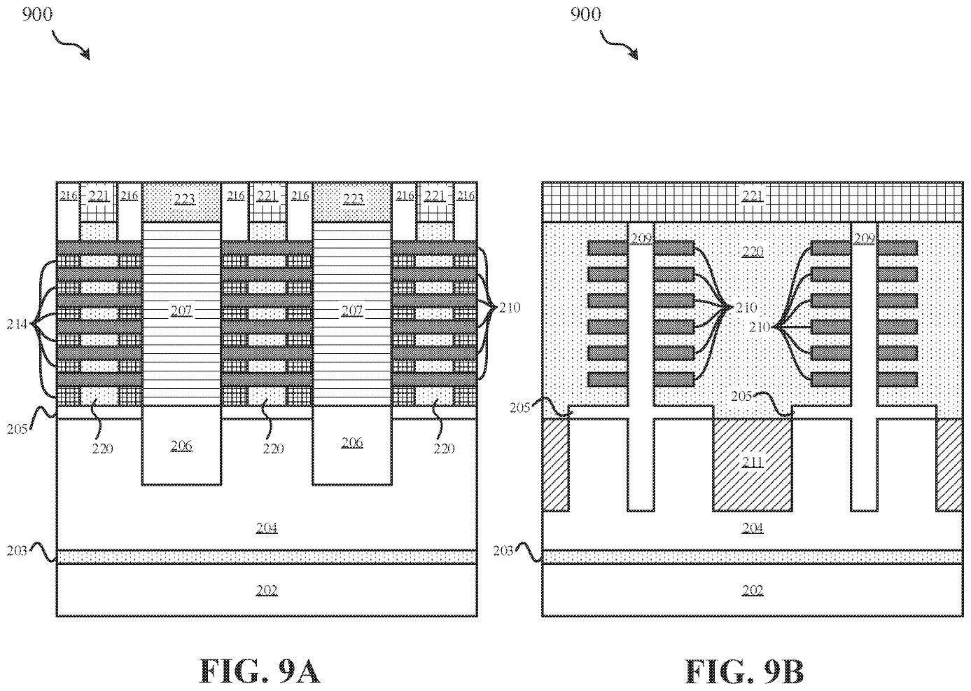

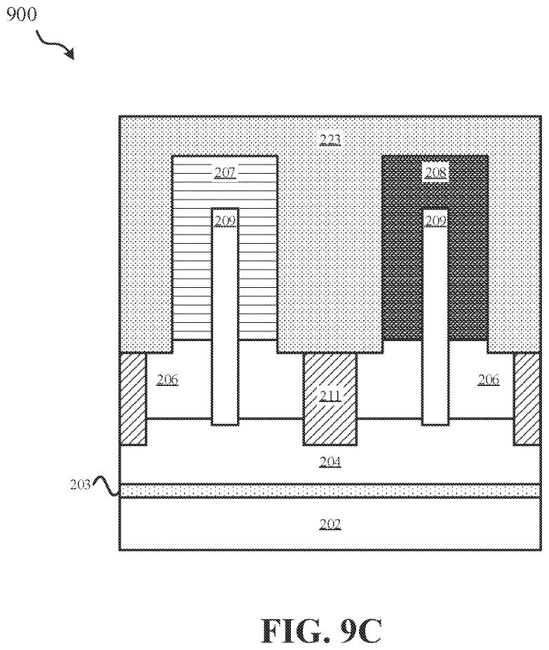

Referring to FIGS. 9A-9C, various cross-sectional views of an intermediate structure corresponding to an intermediate step 900 of forming a semiconductor structure are depicted, according to some embodiments. In intermediate step 900, S/D contact metallization may be performed. Contact metallization may form/establish contact(s) 223 in the semiconductor structure. In some instances, prior to the contact metallization, OPL 222 may be removed. Once OPL 222 is removed, the contact metallization may include depositing metal contact(s) 223 in the open spaces left from the epi cut in intermediate step 800 (FIGS. 8A-C) and the OPL 222 removal. In some instances, metal contact(s) 223 are deposited through ALD, CVD, LCVD, and/or any other deposition technique. In some instances, metal contact(s) 223 include a silicide liner (such as Ti, Ni, NiPt), metal adhesion layer (such as TiN, TaN, etc.), and conductive metal fill (such as W, Co, Ru, etc.).

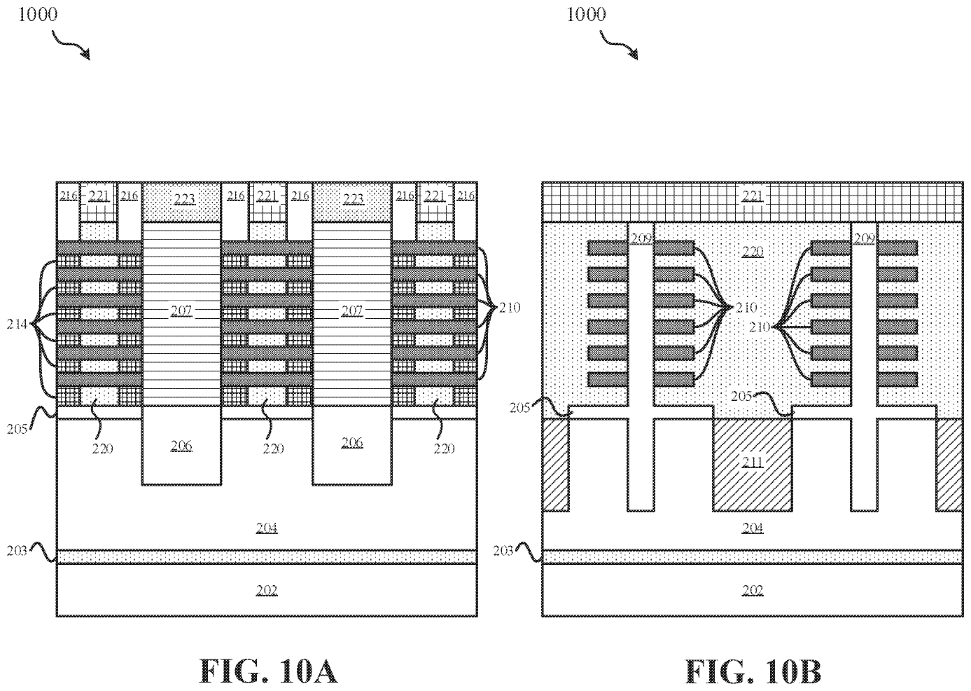

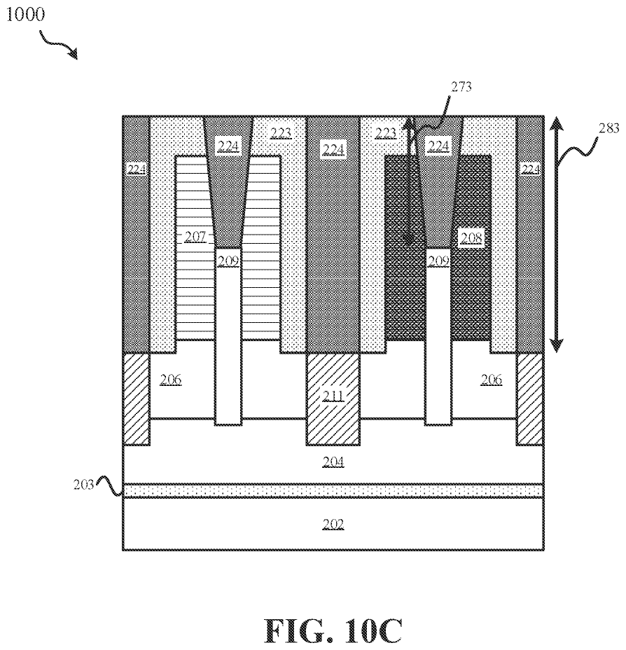

Referring to FIGS. 10A-10C, various cross-sectional views of an intermediate structure corresponding to an intermediate step 1000 of forming a semiconductor structure are depicted, according to some embodiments. In intermediate step 1000, excess portions of metal contact(s) 223 are removed (for example, by a contact cut process) and filled with dielectric 224. For instance, as discussed herein, it may not be desirable to have epis 207 and 208 in contact with, or connected to, each other. Therefore, portions of the metal contact(s) 223 may be cut/removed in order to separate the metal contact(s) 223 in direct contact with epi 207 and the metal contact(s) 223 in direct contact with epi 208. This way, the epis 207 and 208 are not connected through the metal contact(s) 223. In some instances, portions of metal contact(s) 223, as well as a portion of the epis 207 and 208, directly above the dielectric bar 209 may be removed. In some instances, portions of metal contact(s) 223 may be removed through RIE, IBE, or any other etching process.

In some instances, the removal of the excess portions of metal contacts 223 (e.g., the contact cut process) may include performing shallow cuts over the dielectric bar 209 and deep cuts over the STI 211. The shallow cut depth is depicted by depth 273 and the deep cut depth is depicted by depth 283.

Once the desired portions of metal contact(s) 223 are removed, the resulting openings may be filled with dielectric 224. Dielectric 224 may help protect and separate various components of the semiconductor structure. In some instances, dielectric 224 may be dielectric material(s) such as SiN, SiO₂, etc.

In some instances, the epi (207 or 208) on either side of the dielectric bar 209 may be different epis corresponding to different transistors. For example, the epi 207 to the left of the dielectric bar 209 (when viewing from the cross-section depicted in FIG. 10C) may be a first epi corresponding to a first transistor, and the epi 207 to the right of the dielectric bar 209 may be a second epi corresponding to a second transistor. In some instances, as discussed herein, the first transistor and second transistor may be a same type of transistor (e.g., NFET or PFET). Therefore, the first and second epi (e.g., epi 207) may be a same type of epi (e.g., N-epi or P-epi), in some instances. Similarly, in an example, the epi 208 to the left of the dielectric bar 209 (when viewing from the cross-section depicted in FIG. 10C) may be a third epi corresponding to a third transistor, and the epi 208 to the right of the dielectric bar 209 may be a fourth epi corresponding to a fourth transistor. In this example, the third transistor and the fourth transistor may be a same type of transistor and the third epi and fourth epi may be a same type of epi. In instances where the epi on either side of the dielectric bar 209 are different epis (e.g., a first epi and second epi), the epis may be separated by the dielectric bar 209 as well as dielectric 224 (filled in the shallow cut above dielectric bar 209). In some instances, the dielectric 224 may be described as above (when viewing from the cross-section depicted in FIG. 10C) and/or directly connected to dielectric bar 209.

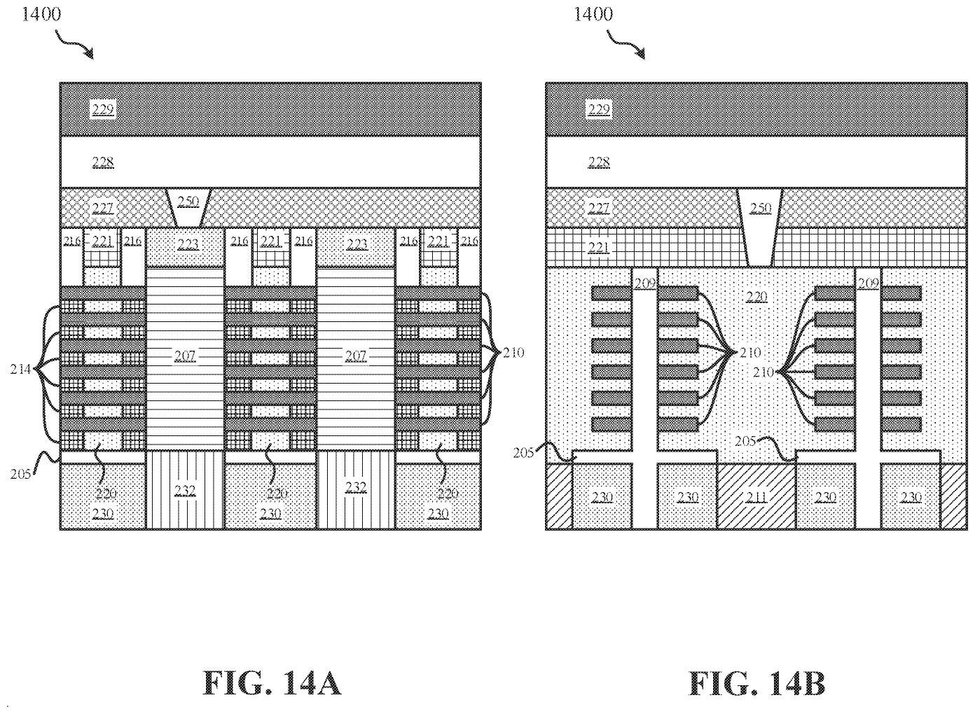

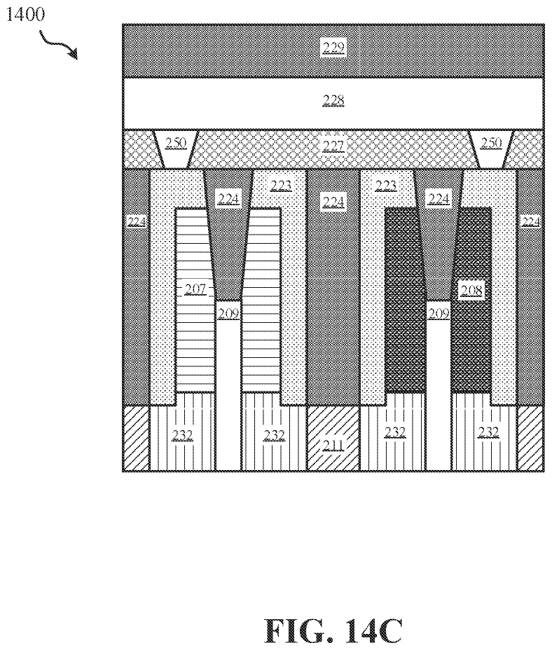

As depicted in FIG. 10C, after portions of metal contact(s) 223 are removed, the remaining portions of metal contact(s) 223 may become the wrapped contacts and/or portions of the wrapped contacts. For instance, contacts 223 may be in direct contact with both sidewall portions and frontside portions of the epis 207 and/or 208. Put differently, contacts 223 may be in direct contact with at least two sides (for example, a top side and a sidewall, when viewing from the cross-section depicted in FIG. 10C) of the epis 207 and/or 208. This may result in a wrapped contact that wraps around multiple portions and/or sides of the epis 207 and/or 208. The large amount of contact between contacts 223 and their corresponding epis 207 and/or 208 may help current reach and travel through the entire epi(s) 207/208, even with S/D resistance (for instance, from the height of the stacked nanosheets 210 in order to help improve scaling of the semiconductor structure). In some instances, metal contact(s) 223 may make up a portion of the wrapped contact(s), and another portion of the wrapped contact(s) may be formed in a later intermediate step (e.g., intermediate step 1400 (FIG. 14C).

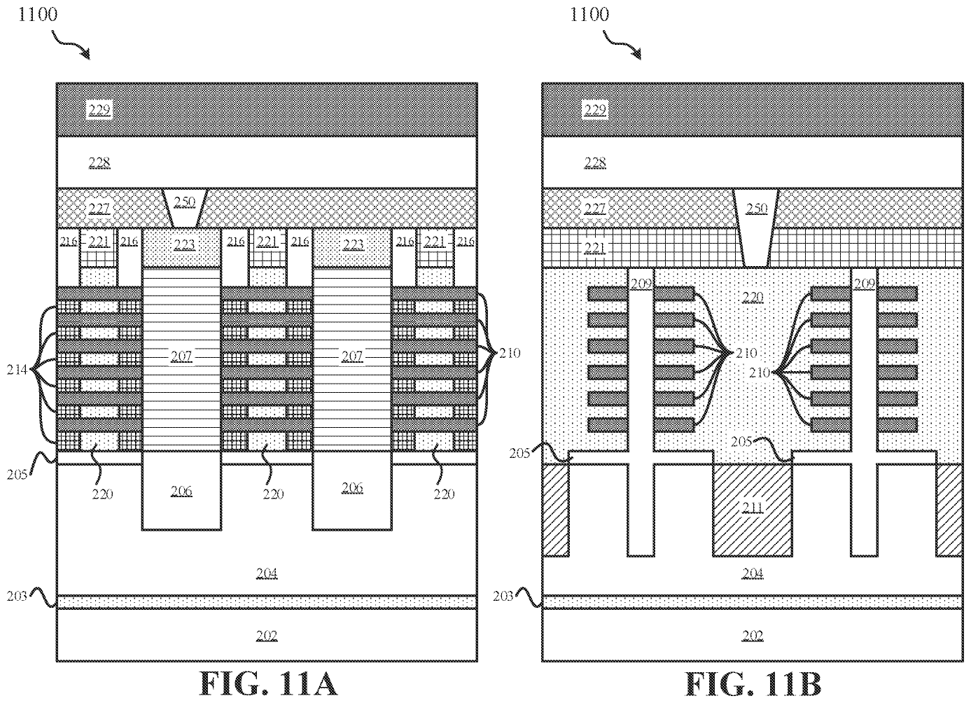

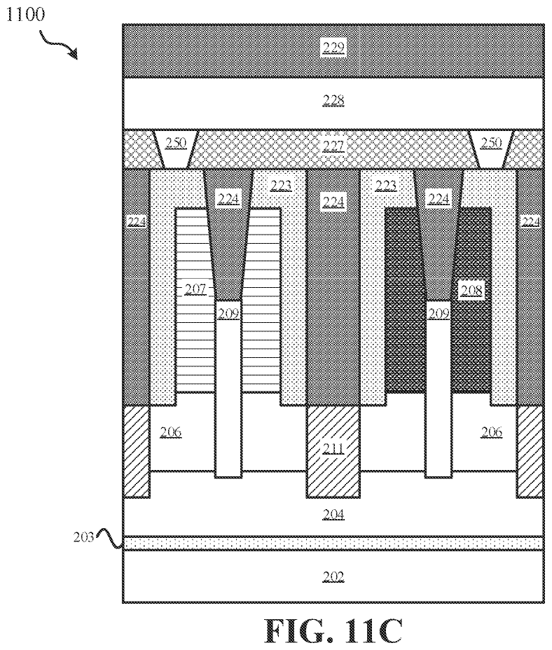

Referring to FIGS. 11A-11C, various cross-sectional views of an intermediate structure corresponding to an intermediate step 1100 of forming a semiconductor structure are depicted, according to some embodiments. Intermediate step 1100 may include forming frontside contacts 250, depositing ILD 227 to help protect and prevent any unwanted current/heat transfer to and/or from the frontside contacts 250. Frontside contacts 250 may also be referred to herein as frontside via contacts 250 to help distinguish from the wrapped contact(s) (discussed further herein) and their multiple portions and/or sides of contact (e.g., frontside, sidewall, and backside). In some instances, frontside contacts 250 are middle of line (MOL) contacts. As depicted in FIGS. 11A-C, frontside contacts 250 may include contact(s) 250 directly connected to metal gate 220, as well as at least one contact 250 directly connected to a top portion of a wrapped contact 223 corresponding to (and directly connected to) epi 207 and at least one contact 250 directly connected to a top portion of a wrapped contact 223 corresponding to (and directly connected to) epi 208. This way, current travelling to/from frontside contacts 250 may travel through wrapped contacts 223.

In some instances, intermediate step 1100 further includes forming/depositing frontside interconnect 228 and carrier wafer 229. In some instances, frontside interconnect 228 is a back end of line (BEOL) interconnect.

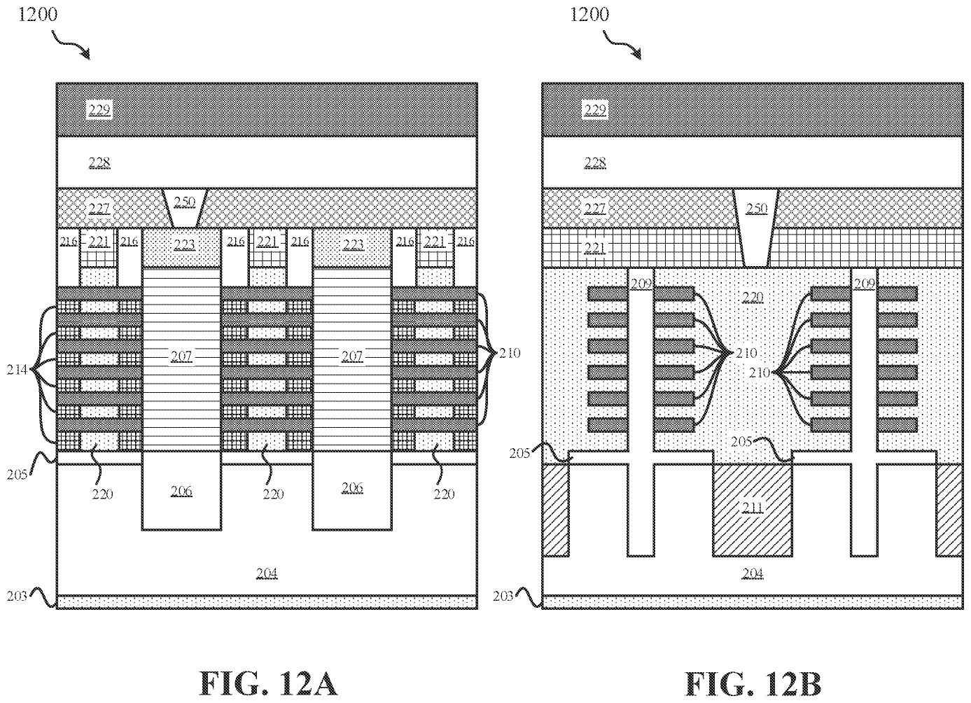

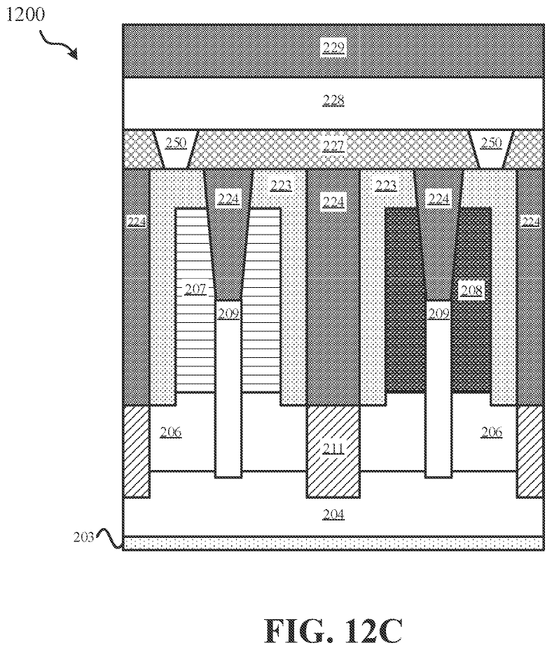

Referring to FIGS. 12A-12C, various cross-sectional views of an intermediate structure corresponding to an intermediate step 1200 of forming a semiconductor structure are depicted, according to some embodiments. Intermediate step 1200 may include removing substrate 202. In some instances, substrate 202 may be removed through grinding, CMP, RIE, IBE, wet etch and/or any other removal/etching process. In some instances, prior to the removal of substrate 202, the wafer (e.g., the structure corresponding to intermediate step 1200) may be flipped.

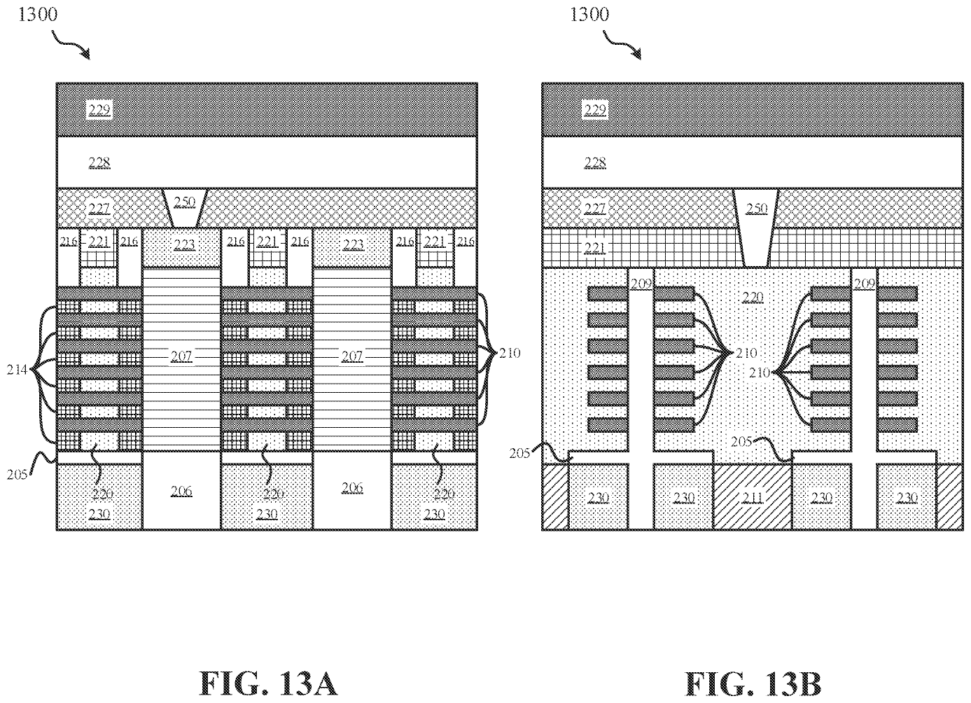

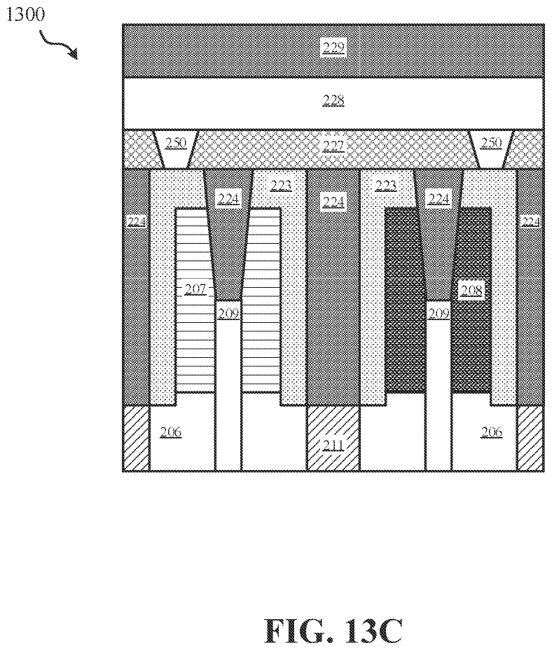

Referring to FIGS. 13A-13C, various cross-sectional views of an intermediate structure corresponding to an intermediate step 1300 of forming a semiconductor structure are depicted, according to some embodiments. Intermediate step 1300 includes removing etch stop layer 203 and substrate 204. In some instances, the removal process for etch stop layer 203 may utilize etch selectivity, where the etchant used may have a high selectivity to etch stop layer 203 (e.g., SiGe). This way, the etch stop layer 203 is removed while preventing any unwanted removal of other components of the intermediate structure. In some instances, substrate 204 (for example, a silicon material) may be removed through RIE, IBE, and/or any other removal/etching process.

In some instances, once the etch stop layer 203 and substrate 204 are removed, the openings created through the removal process (not depicted) may be filled by ILD 230. In some instances, ILD 230 may be dielectric material(s) such as SiN, SiO₂, SiBCN, SiOCN, SiC, SiOC, other oxides, or any other dielectric material. Intermediate step 1300 may also include CMP to polish/smooth exposed portions of the ILD 230.

Referring to FIGS. 14A-14C, various cross-sectional views of an intermediate structure corresponding to an intermediate step 1400 of forming a semiconductor structure are depicted, according to some embodiments. In some instances, intermediate step 1400 includes removing backside contact placeholders 206. As discussed herein, backside contact placeholders 206 may have served as placeholders for the backside contact portions/sides of the wrapped contact(s). To form the actual backside contacts, the backside contact placeholders 206 may be removed. In some instances, the removal may be done using RIE, IBE, and/or any other removal/etching process.

Once the backside contact placeholders 206 are removed, intermediate step 1400 may include depositing/forming backside contacts 232. Forming backside contacts 232 may include depositing a metal material/metal contact (for example, using ALD, CVD, LCVD, and/or any other deposition technique) in the openings (not depicted) created by the removal of backside contact placeholders 206. In some instances, backside contacts 232 may be a same/similar material as contacts 223.

In some instances, backside contact(s) 232 and metal contact(s) 223 may together make up wrapped contact(s) (referred to herein as wrapped contact(s) 223, 232). For instance, metal contact(s) 223 may have both frontside contact and sidewall contact with the epi(s) 207 and/or 208, contact(s) 232 may have backside contact with the epi(s) 207 and/or 208, and together, wrapped contact(s) 223, 232 may have frontside, sidewall, and backside contact with the epi(s) 207 and 208. In some instances, contacts 232 and 223 may be a single continuous component without any distinct barrier between them. In some instances, contacts 232 and 223 may be separate components that are in contact (for example, direct contact) with each other. In some instances, wrapped contact(s) 223, 232 may be described as having contact with multiple sides of the epi(s) 207 and/or 208. For example, contact(s) 223 may have direct contact with at least two sides (e.g., a front side/top side and a sidewall, when viewing from the cross-section depicted in FIG. 14C) of the epi(s) 207 and/or 208. Contact(s) 232 may have direct contact with at least one side (e.g., a back side/bottom side, when viewing from the cross-section depicted in FIG. 14C) of the epi(s) 207 and/or 208. Therefore, in instances where the wrapped contact(s) include contacts 232 and 223, the wrapped contact 223, 232 may have direct contact with at least three sides (i.e., three or more sides) of the epi(s) 207 and/or 208.

Referring to FIGS. 15A-15C, various cross-sectional views of a fully formed semiconductor structure 1500 with dielectric bars and wrapped contacts are depicted, according to some embodiments. Fully formed semiconductor structure 1500 may correspond to semiconductor structure 100 (FIGS. 1A and B) in some instances.

In some instances, to finish forming semiconductor structure 1500 (i.e., to transition from semiconductor structure 1400 to semiconductor 1500), backside interconnect 235, backside contact(s) 270, and additional ILD 230 may be deposited/formed. In some instances, backside interconnect 235 is a BEOL interconnect. In some instances, forming/depositing backside interconnect 235, backside contact(s) 270, and additional ILD 230 may be done using the same/similar steps discussed in relation to intermediate step 1100 (FIGS. 11A-11C). Backside contacts 270 may also be referred to herein as backside via contacts 270 to help distinguish from the wrapped contact(s) 223, 232 and their multiple portions and/or sides of contact (e.g., frontside, sidewall, and backside).

In semiconductor structure 1500, backside via contacts 270 may directly connect to the backside portions 232 (also referred to herein as backside contacts 232) of the wrapped contacts 223, 232. This way, as depicted in FIG. 15C, wrapped contacts 223, 232 have direct contact with both frontside contacts 250 and backside contacts 270, as well as contact with the frontside, sidewall, and backside portions of the S/D epis 207 and 208. This may allow for current to access and travel through the entire S/D epis 207 and 208, even with the additional resistance caused by the added height (when looking from the cross-sections depicted in FIGS. 15A-15C) of the semiconductor structure 1500 due to the scaling benefits from stacking nanosheets 210 and utilizing dielectric bars 209.

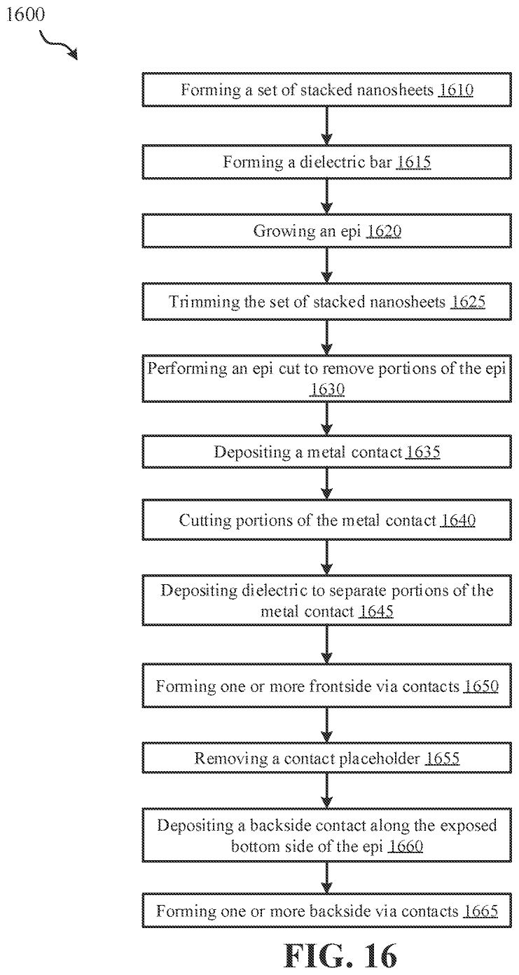

Referring to FIG. 16, a flowchart of an example method 1600 of forming a semiconductor structure (for example, semiconductor structure 100 (FIGS. 1A-B) and/or semiconductor structure 1500 (FIGS. 15A-C)) with a dielectric bar and wrapped contact are depicted, according to some embodiments. In some instances, method 1600 may correspond to intermediate steps 200-1400 (FIGS. 2A-14C).

Method 1600 includes operation 1610 of forming a set of stacked nanosheets. This may correspond to intermediate step 200 (FIGS. 2A-2C) in some instances. In some instances, as depicted in FIGS. 2A-2C, the set of stacked nanosheets (e.g., nanosheets 210 (FIGS. 2A-2C)) may be formed/deposited with sacrificial sheets (e.g., sacrificial sheets 212 (FIGS. 2A-2C)) separating each nanosheet in the stack.

In some instances, method 1600 includes operation 1615 of forming a dielectric bar. This may correspond to intermediate step 200 (FIGS. 2A-2C) in some instances. In some instances, as depicted in FIGS. 2A-2C, the dielectric bar (e.g., 209) may be directly connected to the set of stacked nanosheets. The dielectric bar (e.g., 209) may also be described as separating sets of the stacked nanosheets, in some instances. In some instances, the dielectric bar may separate nanosheets corresponding to a same type of transistor (e.g., an NFET or PFET).

In some instances, method 1600 includes operation 1620 of growing an epi. This may correspond to intermediate step 200 (FIGS. 2A-2C) in some instances. Epi(s) may be grown through processes such as chemical vapor deposition (CVD), vapor-phase epitaxy (VPE), and/or any other epi growth technique. In some instances, as depicted in FIG. 2C, epi(s) may initially be grown to a size larger than necessary in the semiconductor structure. For instance, when a semiconductor structure includes multiple transistors (e.g., an NFET and PFET), the corresponding epis may grow such that they are initially in direct contact with each other. Therefore, as discussed further herein and depicted as operation 1630 in FIG. 16, it may be desirable to cut the epi and remove excess portions.

In some instances, method 1600 includes operation 1625 of trimming the set of stacked nanosheets. Operation 1625 may correspond to intermediate step 400 (FIGS. 4A-4C), in some instances. As discussed in relation to intermediate step 400, in some instances, when the stack of nanosheets is originally formed/deposited, they may be deposited in a wider shape (i.e., with excess width) than desired. Therefore, in some instances, trimming the set of stacked nanosheets may reduce a width between the dielectric bar and an end of the stacked nanosheets.

In some instances, method 1600 includes operation 1630 of performing an epi cut to remove portions of the epi. This may result in an exposed two or more sides of the epi (for example, a top side (e.g., top side 180 (FIG. 1B)) and a sidewall (e.g., sidewall 185 (FIG. 1B)). Operation 1630 may correspond to intermediate step 800 (FIGS. 8A-8C), in some instances. As discussed herein, the initial formation/growth of the epi(s) may result in excess epi material, sometimes even causing direct contact between two epis (as discussed and depicted herein). Therefore, in some instances, method 1600 may include performing an epi cut/cutting the epi to remove excess portions of the epi and separate the epi from any other epis. Additionally, performing an epi cut/cutting the epi may shape the epi such that a wrapped contact (discussed herein) may have the desired direct contact with the epi. For instance, the epi cut may expose the sidewall surface(s) of the epi so that wrapped contact may be formed directly connected to the sidewall(s) of the epi. In some instances, the epi cut may further reduce the size of the epi such that the size (for example, the width, when looking from the cross-sections depicted in FIGS. 2A-15C) of the epi is smaller than the size/width of the backside contact placeholder. This way, the later formed backside contact (discussed herein) can directly contact/connect to the wrapped contact.

In some instances, method 1600 includes operation 1635 of depositing a metal contact around the two or more sides of the epi. The two or more sides may be the exposed two or more sides from operation 1630. Operation 1635 may also be referred to herein as performing contact metallization. Operation 1635 may correspond to intermediate step 900 (FIGS. 9A-C), in some instances. In some instances, the metal contact surrounds exposed portions of an epi. For instance, the metal contact may be directly connected to at least a frontside portion and a sidewall portion of the epi.

In some instances, method 1600 includes operation 1640 of cutting portions of the metal contact (for example, by a contact cut process). This may correspond to intermediate step 1000 (FIGS. 10A-C), in some instances. As discussed in relation to intermediate step 1000, depositing the metal contact may result in excess metal. For instance, the metal contact may electrically connect the epi with another epi, which may not be desired in the semiconductor structure. Therefore, portions of the metal contact may be removed/cut to help separate the epi from any unwanted connections. In some instances, the removal of the excess portions of metal contact (e.g., the contact cut process) may include performing one or more shallow cuts over the dielectric bar 209 and one or more deep cuts over shallow trench isolation (STI).

In some instances, the metal contact may be a wrapped contact. For example, the metal contact (such as contact 223 (FIGS. 10C-15C)) may wrap around portions of an epi and may be in direct contact with at least a frontside and a sidewall of the epi. In some instances, the metal contact may make up a portion of a wrapped contact, and a second portion of a wrapped contact will be formed in operation 1650. For example, in some instances, the metal contact (such as contact 223 (FIGS. 10C-15C)) along with another contact (such as contact 232 (FIGS. 14C-15C)) may together make up a wrapped contact.

In some instances, method 1600 includes operation 1645 of depositing dielectric to separate portions of the metal contact. This may correspond to intermediate step 1000 (FIG. 10A-C), in some instances. As discussed in relation to intermediate step 1000, once the desired portions of the metal contact are removed, the resulting openings may be filled with dielectric. The dielectric may help separate and protect portions of the metal contact, as well as the metal contact itself, from other metal contacts as well as the various components of the device. Depositing the dielectric may result in one or more wrapped contacts separated by the dielectric.

In some instances, method 1600 includes operation 1650 of forming one or more frontside via contacts. Operation 1645 may correspond to intermediate step 1100 (FIGS. 11A-C), in some instances. As discussed herein, the wrapped contact may have direct contact to one or more frontside via contacts (e.g., frontside contacts 250 (FIGS. 11A-C)). This way, current travelling to/from the frontside via contacts may travel through the metal contact and the wrapped contact.

In some instances, method 100 includes operation 1655 of removing a contact placeholder. This may correspond to intermediate step 1400 (FIGS. 14A-C), in some instances. As discussed herein, a contact placeholder (such as backside contact placeholder 206) may be used to serve as a placeholder for the backside contact portion of the wrapped contact. Therefore, before performing a metal fill and forming the backside contact, the contact placeholder may need to be removed. Removing the contact placeholder may result in an exposed side of the epi (for example, an exposed bottom side of the epi).

In some instances, method 1600 includes operation 1660 of depositing a backside contact along the exposed bottom side of the epi. Operation 1660 may correspond to intermediate step 1400 (FIGS. 14A-C), in some instances. In some instances, the backside contact is directly connected to the epi and the metal contact. For instance, the metal contact may create frontside contact and sidewall contact for the epi, and the backside contact may connect to a backside portion, or a bottom side, of the epi. In some instances, as discussed herein, the wrapped contact includes the metal contact and the backside contact. In these instances, the wrapped contact may have frontside contact, sidewall contact, and backside contact with the epi.

In some instances (not depicted), for example, when the wrapped contact is a contact such as contact 223 (FIGS. 10C-15C), method 1600 may include depositing a metal contact (1635) and cutting portions of the metal contact (1640), but may not include removing a contact placeholder (1655) and depositing a backside contact (1660). In other instances, when the wrapped contact includes a contact such as contact 223 (FIGS. 10C-15C) as well as a contact such as contact 232 (FIGS. 14C-15C), method 1600 may further include removing a contact placeholder (1655) and depositing a backside contact (1660) (for example, backside contact 232).

In some instances, method 1600 includes operation 1665 of forming one or more backside via contacts. Forming one or more backside via contacts may be further discussed herein in relation to semiconductor structure 1500 (FIGS. 15A-C). In some instances, the one or more backside via contacts may directly connect to the backside portion/backside contact portion of the wrapped contact. This way, the wrapped contact may have direct contact with both frontside via contact(s) and backside via contact(s), as well as contact with the frontside, sidewall, and backside portions of the epi. This may allow for current to access and travel through the entire epi, thus allowing the transistor and the semiconductor to function properly.

In some instances, method 1600 may include additional steps not depicted in FIG. 16. For example, method 1600 may include any of the intermediate steps (e.g., 200-1400 (FIGS. 2A-14C)) discussed herein in relation to forming semiconductor structure 1500 (FIGS. 15A-C) and/or semiconductor structure 100 (FIGS. 1A-B).

The present invention may be a system, a method, a computer program product, etc. at any possible technical detail level of integration.

Aspects of the present invention are described herein with reference to flowchart illustrations and/or block diagrams of methods, apparatus (systems), and computer program products according to embodiments of the invention. It will be understood that each block of the flowchart illustrations and/or block diagrams, and combinations of blocks in the flowchart illustrations and/or block diagrams, can be implemented by computer readable program instructions.

These computer readable program instructions may be provided to a processor of a general-purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks. These computer readable program instructions may also be stored in a computer readable storage medium that can direct a computer, a programmable data processing apparatus, and/or other devices to function in a particular manner, such that the computer readable storage medium having instructions stored therein comprises an article of manufacture including instructions which implement aspects of the function/act specified in the flowchart and/or block diagram block or blocks. The computer readable program instructions may also be loaded onto a computer, other programmable data processing apparatus, or other device to cause a series of operational steps to be performed on the computer, other programmable apparatus or other device to produce a computer implemented process, such that the instructions which execute on the computer, other programmable apparatus, or other device implement the functions/acts specified in the flowchart and/or block diagram block or blocks.

The flowchart and block diagrams in the Figures illustrate the architecture, functionality, and operation of possible implementations of systems, methods, and computer program products according to some embodiments of the present invention. In this regard, each block in the flowchart or block diagrams may represent a module, segment, or portion of instructions, which comprises one or more executable instructions for implementing the specified logical function(s). In some alternative implementations, the functions noted in the blocks may occur out of the order noted in the Figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

The descriptions of the various embodiments of the present disclosure have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor structure, wherein the semiconductor structure comprises:
a first transistor, wherein the first transistor comprises:
an epi;
a dielectric bar; and
a wrapped contact, wherein the wrapped contact has direct contact with three or more sides of the epi.

2. The semiconductor structure of claim 1, wherein the direct contact with three or more sides of the epi comprises direct contact with a bottom side of the epi.

3. The semiconductor structure of claim 2, wherein the direct contact with three or more sides of the epi further comprises direct contact with a top side and one or more sidewalls of the epi.

4. The semiconductor structure of claim 2, wherein a first width of a backside portion of the wrapped contact is greater than a second width of the epi.

5. The semiconductor structure of claim 1, wherein a first height of the dielectric bar in a source/drain region of the semiconductor structure is less than a second height of the dielectric bar in a gate region of the semiconductor structure.

6. The semiconductor structure of claim 1, wherein:
the first transistor further comprises stacked nanosheets; and
a width between the dielectric bar and an end of the stacked nanosheets is a minimum of 6 nanometers and a maximum of 30 nanometers.

7. The semiconductor structure of claim 1, further comprising:
a second transistor, wherein the first transistor is an NFET and the second transistor is a PFET.

8. The semiconductor structure of claim 7, wherein N2P space between the first transistor and the second transistor is a minimum of 25 nanometers and a maximum of 70 nanometers.

9. A system, wherein the system comprises:
a semiconductor structure, wherein the semiconductor structure comprises:
a first transistor, wherein the first transistor comprises:
an epi;
stacked nanosheets;
a dielectric bar, wherein the dielectric bar is directly connected to the stacked nanosheets; and
a wrapped contact, wherein the wrapped contact has direct contact with three or more sides of the epi.

10. The system of claim 9, wherein the direct contact with three or more sides of the epi comprises direct contact with a bottom side of the epi.

11. The system of claim 10, wherein the direct contact with three or more sides of the epi further comprises direct contact with a top side and one or more sidewalls of the epi.

12. The system of claim 10, wherein a first width between the dielectric bar and an end of the stacked nanosheets is less than a second width between the dielectric bar and shallow trench isolation.

13. The system of claim 9, further comprising:
a second transistor, wherein the second transistor is a same type as the first transistor, and wherein the second transistor comprises a second set of stacked nanosheets.

14. The system of claim 13, wherein the dielectric bar is directly connected to the second set of stacked nanosheets.

15. The system of claim 13, wherein the second transistor further comprises a second epi, wherein:
the epi and the second epi are separated by the dielectric bar and dielectric.

16. A method of forming a semiconductor structure, the method comprising:
forming a set of stacked nanosheets;
forming a dielectric bar, wherein the dielectric bar is directly connected to the set of stacked nanosheets;
growing an epi;
performing an epi cut to remove portions of the epi, resulting in an exposed two or more sides of the epi;
depositing metal contact around the two or more sides of the epi; and
depositing dielectric to separate portions of the metal contact, resulting in one or more wrapped contacts separated by the dielectric.

17. The method of claim 16, wherein the two or more sides comprise a top side and a sidewall of the epi.

18. The method of claim 16, further comprising:
removing a contact placeholder, resulting in an exposed bottom side of the epi; and
depositing a backside contact along the exposed bottom side of the epi, wherein the backside contact is directly connected to the bottom side of the epi and the metal contact, and wherein the one or more wrapped contacts comprises the metal contact and the backside contact.

19. The method of claim 16, further comprising:
cutting portions of the metal contact, wherein the dielectric is deposited subsequent to the cutting.

20. The method of claim 16, further comprising:
trimming the set of stacked nanosheets, wherein trimming the set of stacked nanosheets reduces a width between the dielectric bar and an end of the stacked nanosheets.
